(19) United States
(12) Patent Application Publication
(10) Pub. No.: US 2021/0349391 A1
(43) Pub. Date: Nov. 11, 2021

(54) PHOTORESIST UNDER-LAYER AND METHOD OF FORMING PHOTORESIST PATTERN

(71) Applicant: TAIWAN SEMICONDUCTOR MANUFACTURING CO., LTD., Hsinchu (TW)

(72) Inventors: An-Ren ZI, Hsinchu City (TW); Chin-Hsiang LIN, Hsinchu (TW); Ching-Yu CHANG, Yuansun Village (TW)

(21) Appl. No.: 16/870,704

(22) Filed: May 8, 2020

(51) Int. Cl. G03F 7/11; G03F 7/16; G03F 7/038; G03F 7/039; G03F 7/004; G03F 7/20; G03F 7/38; G03F 7/32; H01L 21/027

(52) U.S. Cl. CPC G03F 7/11; G03F 7/168; G03F 7/038; G03F 7/039; H01L 21/0274; G03F 7/2002; G03F 7/38; G03F 7/32; G03F 7/0045

(57) ABSTRACT

A method of manufacturing a semiconductor device includes forming a photoresist under-layer including a photoresist under-layer composition over a semiconductor substrate, and forming a photoresist layer including a photoresist composition over the photoresist under-layer. The photoresist layer is selectively exposed to actinic radiation and the photoresist layer is developed to form a pattern in the photoresist layer. The photoresist under-layer composition includes a polymer having pendant acid-labile groups, a polymer having crosslinking groups or a polymer having pendant carboxylic acid groups, an acid generator, and a solvent. The photoresist composition includes a polymer, a photoactive compound, and a solvent.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed. In one example, advanced lithography patterning technologies are implemented to form various patterns, such as gate electrodes and metal lines, on semiconductor wafers. Lithography patterning technologies include coating a resist material on the surface of a semiconductor wafer.

Extreme ultraviolet lithography (EUVL) has been developed to form smaller semiconductor device feature size and increase device density on a semiconductor wafer. As pattern features become smaller and pattern pitch decreases residual photoresist and scum remaining in the developed areas lead to pattern defects. Complete removal of photoresist in the developed areas is desirable in EUVL.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A, 1B, 1C, 1D, 1E, 1F, 1G, and 1H are cross sectional views of sequential operations for manufacturing a semiconductor device according to an embodiment of the disclosure. FIGS. 1I and 1J are cross sectional views of an alternative embodiment of manufacturing a semiconductor device according to the disclosure. FIGS. 1K and 1L are cross sectional views of an alternative embodiment of manufacturing a semiconductor device according to the disclosure.

FIG. 2A illustrates a polymer with an acid labile group according to embodiments of the disclosure. FIG. 2B illustrates examples of acid labile groups according embodiments of the disclosure. FIG. 2C illustrates an acid labile group de-protect reaction according to embodiments of the disclosure.

FIG. 3A illustrates a polymer with a crosslinking group according to embodiments of the disclosure. FIG. 3B illustrates examples of crosslinking groups according embodiments of the disclosure.

FIG. 4 illustrates examples of photoacid generators according to embodiments of the disclosure.

FIGS. 5A and 5B show process stages of a sequential operation according to embodiments of the disclosure.

FIGS. 6A, 6B, 6C, 6D, 6E, 6F, 6G, and 6H are cross sectional views of sequential operations for manufacturing a semiconductor device according to an embodiment of the disclosure. FIGS. 6I and 6J are cross sectional views of an alternative embodiment of manufacturing a semiconductor device according to the disclosure. FIGS. 6K and 6L are cross sectional views of an alternative embodiment of manufacturing a semiconductor device according to the disclosure.

FIG. 7 illustrates examples of thermal acid generators according to embodiments of the disclosure.

FIGS. 8A, 8B, 8C, 8D, 8E, 8F, 8G, and 8H are cross sectional views of sequential operations for manufacturing a semiconductor device according to an embodiment of the disclosure. FIGS. 8I and 8J are cross sectional views of an alternative embodiment of manufacturing a semiconductor device according to the disclosure. FIGS. 8K and 8L are cross sectional views of an alternative embodiment of manufacturing a semiconductor device according to the disclosure.

FIG. 9 illustrates examples of photobase generators according to embodiments of the disclosure.

FIGS. 10A, 10B, 10C, 10D, 10E, 10F, 10G, and 10H are cross sectional views of sequential operations for manufacturing a semiconductor device according to an embodiment of the disclosure. FIGS. 10I and 10J are cross sectional views of an alternative embodiment of manufacturing a semiconductor device according to the disclosure. FIGS. 10K and 10L are cross sectional views of an alternative embodiment of manufacturing a semiconductor device according to the disclosure.

FIG. 11A illustrates examples of alcohols according to embodiments of the disclosure.

FIG. 11B illustrates a reaction of an alcohol and a generated acid according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

As feature size decreases below 60 nm pattern pitch, line width resolution suffers. Residual photoresist or scum is difficult to remove in small pitch and high aspect ratio patterns. To improve line width resolution in extreme ultraviolet (EUV) lithography operations a photoresist under-layer is used according to embodiments of the disclosure. The photoresist under-layer is removed during the development operation, thereby removing any residual photoresist or scum overlying the photoresist under-layer.

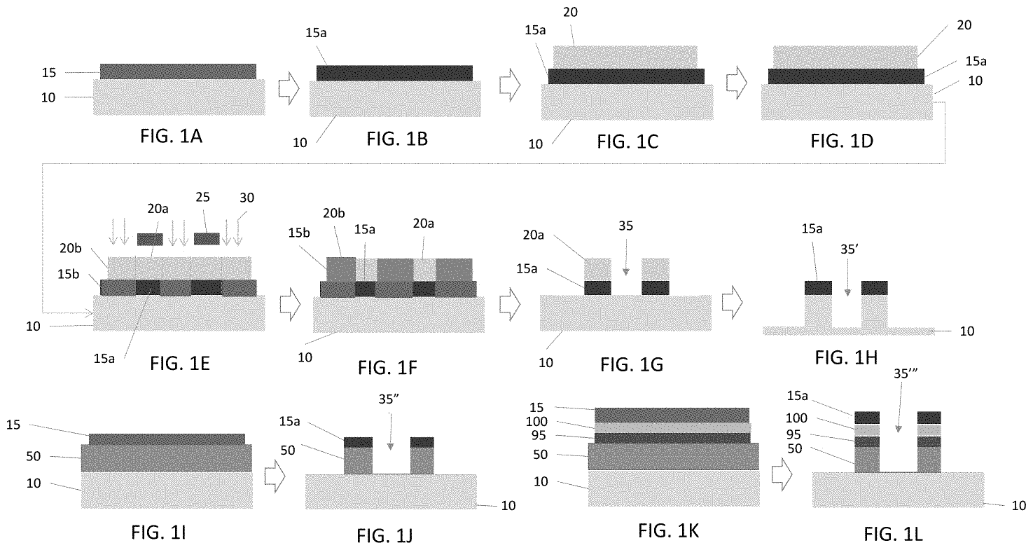

FIGS. 1A-1H are cross sectional views of sequential operations for manufacturing a semiconductor device according to an embodiment of the disclosure. FIG. 1A shows a photoresist under-layer 15 formed over a substrate 10, such as a wafer. In some embodiments, the under-layer 15 is deposited as a liquid mixture and the substrate 10 is rotated while the under-layer is deposited over the substrate 10.

In some embodiments, the substrate 10 includes a single crystalline semiconductor layer on at least its surface portion. The substrate may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate is a silicon layer of an SOI (silicon-on insulator) substrate. In certain embodiments, the substrate is made of crystalline Si. In certain embodiments, the substrate is a silicon wafer.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate. The germanium concentration of the SiGe buffer layers may increase from 30 atomic % for the bottom-most buffer layer to 70 atomic % for the top-most buffer layer.

In some embodiments, the substrate includes at least one metal, metal alloy, and metal/nitride/sulfide/oxide/silicide having the formula MXₐ, where M is a metal and X is N, S, Se, O, Si, and a is from about 0.4 to about 2.5. In some embodiments, the substrate includes titanium, aluminum, cobalt, ruthenium, titanium nitride, tungsten nitride, tantalum nitride, and combinations thereof.

In some embodiments, the substrate 10 includes a dielectric layer having at least silicon, metal oxide, and metal nitride of the formula MXb, where M is a metal or Si, X is N or O, and b ranges from about 0.4 to about 2.5. Ti, Al, Hf, Zr, and La are suitable metals, M, in some embodiments. In some embodiments, the substrate includes silicon dioxide, silicon nitride, aluminum oxide, hafnium oxide, lanthanum oxide, and combinations thereof.

In some embodiments, the photoresist under-layer 15 includes a photoresist under-layer composition including a polymer having pendant acid-labile groups, a polymer having crosslinking groups, an acid generator, and a solvent. In some embodiments, the acid generator is a photoacid generator.

In some embodiments, the pendant acid-labile groups are about 20 wt. % to about 80 wt. % of the polymer having pendant acid-labile groups. If the amount of pendant acid-labile groups is less than about 20 wt. % the photoresist under-layer may have insufficient beneficial effects. If the amount of the pendant acid-labile groups is greater than about 80 wt. % the polymer having pendant acid-labile groups may lack sufficient solubility in the solvent. In some embodiments, the crosslinking groups are about 20 wt. % to about 80 wt. % of the polymer having the crosslinking groups. If the amount of the crosslinking groups is less than about 20 wt. % the photoresist under-layer may have insufficient resistance to the photoresist developer. If the amount of the crosslinking groups is greater than about 80 wt. % the polymer having the crosslinking groups may lack sufficient solubility in the solvent. In some embodiments, the pendant acid-labile groups are about 30 wt. % to about 70 wt. % of the polymer having pendant acid-labile groups, and the crosslinking groups are about 30 wt. % to about 70 wt. % of the polymer having the crosslinking groups. In some embodiments, the acid labile group is connected to the polymer having the pendant acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In some embodiments, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group.

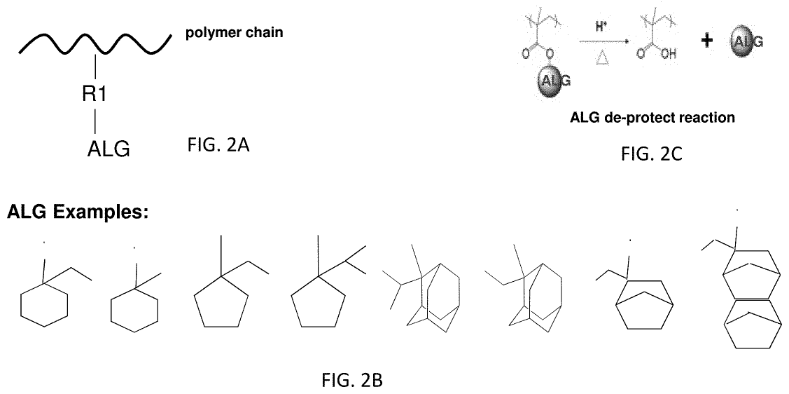

FIG. 2A illustrates a polymer with an acid labile group (ALG) according to embodiments of the disclosure. FIG. 2B illustrates examples of acid labile groups according embodiments of the disclosure. Acids generated during a heating operation or during exposure to actinic radiation cleave the ALGs. FIG. 2C illustrates an ALG de-protect reaction according to embodiments of the disclosure.

In some embodiments, the polymer in the photoresist under-layer includes a hydrocarbon structure (such as an alicyclic hydrocarbon structure) that includes a repeating unit that forms a skeletal backbone of the polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

Specific structures that are utilized for the repeating unit of the hydrocarbon structure in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like.

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, tetracyclododecane, or the like.

The group which will decompose, otherwise known as an acid labile group, is attached to the hydrocarbon structure so that, it will react with the acids/bases/free radicals generated by the photoacid generator during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsylfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

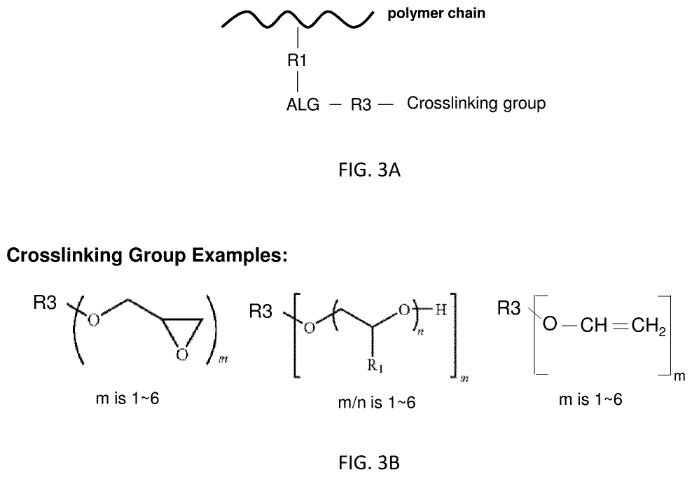

FIG. 3A illustrates a polymer with a crosslinking group according to embodiments of the disclosure. In some embodiments, the ALG and crosslinking group are attached to the same polymer backbone. FIG. 3B illustrates examples of crosslinking groups according embodiments of the disclosure.

In some embodiments, the polymer main chain having the pendant ALG or crosslinking group is a hydrocarbon chain. In some embodiments, the polymer is a polyhydroxystyrene, polyacrylate, or polymethylmethacrylate based polymer.

In some embodiments, the polymer resin also includes other groups attached to the hydrocarbon structure that help to improve a variety of properties of the polymerizable resin. Optionally, the polymer resin includes one or more alicyclic hydrocarbon structures that do not also contain a group, which will decompose in some embodiments. In some embodiments, the hydrocarbon structure that does not contain a group which will decompose includes structures such as 1-adamantyl(meth)acrylate, tricyclodecanyl (meth)acrylate, cyclohexyl (methacrylate), combinations of these, or the like.

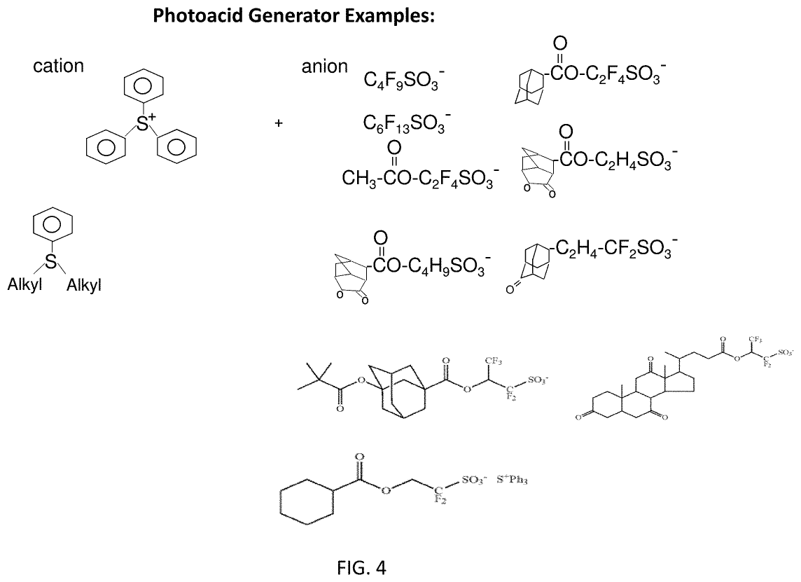

Examples of photoacid generators according to embodiments of the disclosure include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like. Structures of photoacid generators according to some embodiments of the disclosure are shown in FIG. 4.

In some embodiments, the concentration of the photoacid generator ranges from about 5 wt. % to about 40 wt. % based on the total weight of the photoacid generator and the polymers. If the concentration of the photoacid generator is less than about 5 wt. % the photoresist under-layer may have insufficient beneficial effects. If the amount of the photoacid generator is greater than about 40 wt. % the cost of the photoresist under-layer material composition may become excessive with no significant improvement in beneficial properties of photoresist under-layer. In other embodiments, the concentration of the photoacid generator ranges from about 10 wt. % to about 25 wt. % based on the total weight of the photoacid generator and the polymers.

In some embodiments, the photoresist under-layer 15 has a thickness ranging from about 2 nm to about 1 μm. In some embodiments, the thickness of the photoresist under-layer ranges from about 5 nm to about 500 nm, and in other embodiments, the thickness of the photoresist under-layer ranges from about 10 nm to about 200 nm.

The individual components of the photoresist under-layer composition are placed into a solvent in order to aid in the mixing and dispensing of the photoresist under-layer. To aid in the mixing and dispensing of the photoresist, the solvent is chosen at least in part based upon the materials chosen for the polymers as well as the photoacid generators. In some embodiments, the solvent is chosen such that the polymer resins and the photoacid generators can be evenly dissolved into the solvent and dispensed upon the layer to be patterned.

In some embodiments, the solvent is an organic solvent, and includes one or more of any suitable solvent such as ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

Specific examples of materials that may be used as the solvent for the photoresist under-layer composition include, acetone, methanol, ethanol, propanol, isopropanol (IPA), n-butanol, toluene, xylene, 4-hydroxy-4-methyl-2-pentatone, tetrahydrofuran (THF), methyl ethyl ketone, cyclohexanone (CHN), methyl isoamyl ketone, 2-heptanone (MAK), ethylene glycol, 1-ethoxy-2-propanol, methyl isobutyl carbinol (MIBC), ethylene glycol monoacetate, ethylene glycol dimethyl ether, ethylene glycol dimethyl ether, ethylene glycol methylethyl ether, ethylene glycol monoethyl ether, methyl cellosolve acetate, ethyl cellosolve acetate, diethylene glycol, diethylene glycol monoacetate, diethylene glycol monomethyl ether, diethylene glycol diethyl ether, diethylene glycol dimethyl ether, diethylene glycol ethylmethyl ether, diethethylene glycol monoethyl ether, diethylene glycol monobutyl ether, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanate, methyl 3-methoxypropionate, ethyl 3-methoxypropionate, methyl 3-ethoxypropionate, ethyl 3-ethoxypropionate, methyl acetate, ethyl acetate, propyl acetate, n-butyl acetate (nBA), methyl lactate, ethyl lactate (EL), propyl lactate, butyl lactate, propylene glycol, propylene glycol monoacetate, propylene glycol monoethyl ether acetate, propylene glycol monomethyl ether acetate, propylene glycol monopropyl methyl ether acetate, propylene glycol monobutyl ether acetate, propylene glycol monobutyl ether acetate, propylene glycol monomethyl ether propionate, propylene glycol monoethyl ether propionate, propylene glycol methyl ether acetate, propylene glycol ethyl ether acetate, ethylene glycol monomethyl ether acetate, ethylene glycol monoethyl ether acetate, propylene glycol monomethyl ether, propylene glycol monoethyl ether, propylene glycol monopropyl ether, propylene glycol monobutyl ether, ethylene glycol monomethyl ether, ethylene glycol monoethyl ether, ethyl 3-ethoxypropionate, methyl 3-methoxypropionate, methyl 3-ethoxypropionate, and ethyl 3-methoxypropionate, β-propiolactone, β-butyrolactone, γ-butyrolactone (GBL), α-methyl-γ-butyrolactone, β-methyl-γ-butyrolactone, γ-valerolactone, γ-caprolactone, γ-octanoic lactone, α-hydroxy-γ-butyrolactone, 2-butanone, 3-methylbutanone, pinacolone, 2-pentanone, 3-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-pentene-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, 3-methylcycloheptanone, propylene carbonate, vinylene carbonate, ethylene carbonate, butylene carbonate, acetate-2-methoxyethyl, acetate-2-ethoxyethyl, acetate-2-(2-ethoxyethoxy)ethyl, acetate-3-methoxy-3-methylbutyl, acetate-1-methoxy-2-propyl, dipropylene glycol, monomethylether, monoethylether, monopropylether, monobutylether, monophenylether, dipropylene glycol monoacetate, dioxane, methyl pyruvate, ethyl pyruvate, propyl pyruvate, methyl methoxypropionate, ethyl ethoxypropionate, n-methylpyrrolidone (NMP), 2-methoxyethyl ether (diglyme), ethylene glycol monomethyl ether, propylene glycol monomethyl ether, methyl propionate, ethyl propionate, ethyl ethoxy propionate, methylethyl ketone, cyclohexanone, 2-heptanone, cyclopentanone, cyclohexanone, ethyl 3-ethoxypropionate, propylene glycol methyl ether acetate (PGMEA), methylene cellosolve, 2-ethoxyethanol, N-methylformamide, N,N-dimethylformamide (DMF), N-methylformanilide, N-methylacetamide, N,N-dimethylacetamide, dimethylsulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, phenyl cellosolve acetate, or the like.

As one of ordinary skill in the art will recognize, the materials listed and described above as examples of materials that may be used for the solvent component of the photoresist under-layer composition are merely illustrative and are not intended to limit the embodiments. Rather, any suitable materials that dissolve the polymers and the photoacid generator may be used to help mix and apply the photoresist under-layer. All such materials are fully intended to be included within the scope of the embodiments.

In some embodiments, the method includes a first heating of the photoresist under-layer at a temperature of about 40° C. to about 200° C. for 10 seconds to 5 minutes to form a cross-linked photoresist under-layer composition 15a, as shown in FIG. 1B. The heating causes the crosslinking groups to cross-link. In some embodiments, the first heating is performed at a temperature of about 60° C. to about 170° C. for about 20 seconds to about 3 minutes. In other embodiments, the first heating is performed at a temperature of about 80° C. to about 140° C. for about 30 seconds to about 2 minutes.

A photoresist composition is subsequently disposed over the cross-linked photoresist under-layer composition 15a on the substrate 10 to form a photoresist layer 20, as shown in FIG. 1C. In some embodiments, the substrate 10 is rotated (spinned) during or after the photoresist layer 20 is deposited, spreading the photoresist composition across the surface of the cross-linked photoresist under-layer composition 15a.

The photoresist layer 20 is a photosensitive layer that is patterned by exposure to actinic radiation and development. Typically, the chemical properties of the photoresist regions struck by incident radiation change in a manner that depends on the type of photoresist used. Whether a resist is a positive tone or negative tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent. Further, in some negative tone photoresists developed with the TMAH solution, the unexposed regions of the photoresist are removed by the TMAH, and the exposed regions of the photoresist, that undergo cross-linking upon exposure to actinic radiation, remain on the substrate after development.

Photoresists according to the present disclosure include a polymer along with one or more photoactive compounds (PACs) in a solvent, in some embodiments. In some embodiments, the polymer includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

Specific structures that are utilized for the repeating unit of the hydrocarbon structure in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like.

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, tetracyclododecane, or the like.

The group which will decompose, otherwise known as a leaving group or, in some embodiments in which the PAC is a photoacid generator, an acid labile group, is attached to the hydrocarbon structure so that, it will react with the acids/bases/free radicals generated by the PACs during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsylfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like. Examples of ALG according to some embodiments of the disclosure are shown FIG. 2B.

In some embodiments, the polymer also includes other groups attached to the hydrocarbon structure that help to improve a variety of properties of the polymerizable resin. For example, inclusion of a lactone group to the hydrocarbon structure assists to reduce the amount of line edge roughness after the photoresist has been developed, thereby helping to reduce the number of defects that occur during development. In some embodiments, the lactone groups include rings having five to seven members, although any suitable lactone structure may alternatively be used for the lactone group.

In some embodiments, the polymer includes groups that can assist in increasing the adhesiveness of the photoresist layer to underlying structures (e.g., substrate). Polar groups may be used to help increase the adhesiveness. Suitable polar groups include hydroxyl groups, cyano groups, or the like, although any suitable polar group may, alternatively, be used.

Optionally, the polymer includes one or more alicyclic hydrocarbon structures that do not also contain a group, which will decompose in some embodiments. In some embodiments, the hydrocarbon structure that does not contain a group which will decompose includes structures such as 1-adamantyl(meth)acrylate, tricyclodecanyl (meth)acrylate, cyclohexyl (methacrylate), combinations of these, or the like.

In some embodiments, the polymer is a polyhydroxystyrene, polyacrylate, or polymethylmethacrylate based polymer.

Additionally, some embodiments of the photoresist include one or more photoactive compounds (PACs). The PACs are photoactive components, such as photoacid generators, photobase generators, free-radical generators, or the like. The PACs may be positive-acting or negative-acting. In some embodiments in which the PACs are a photoacid generator, the PACs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like. Structures of photoacid generators according to some embodiments of the disclosure are shown in FIG. 4.

In some embodiments in which the PACs are free-radical generators, the PACs include n-phenylglycine; aromatic ketones, including benzophenone, N,N′-tetramethyl-4,4′-diaminobenzophenone, N,N′-tetraethyl-4,4′-diaminobenzophenone, 4-methoxy-4′-dimethylaminobenzo-phenone, 3,3′-dimethyl-4-methoxybenzophenone, p,p′-bis(dimethylamino)benzo-phenone, p,p′-bis(diethylamino)-benzophenone; anthraquinone, 2-ethylanthraquinone; naphthaquinone; and phenanthraquinone; benzoins including benzoin, benzoinmethylether, benzoinisopropylether, benzoin-n-butylether, benzoin-phenylether, methylbenzoin and ethylbenzoin; benzyl derivatives, including dibenzyl, benzyldiphenyldisulfide, and benzyldimethylketal; acridine derivatives, including 9-phenylacridine, and 1,7-bis(9-acridinyl)heptane; thioxanthones, including 2-chlorothioxanthone, 2-methylthioxanthone, 2,4-diethylthioxanthone, 2,4-dimethylthioxanthone, and 2-isopropylthioxanthone; acetophenones, including 1,1-dichloroacetophenone, p-t-butyldichloro-acetophenone, 2,2-diethoxyacetophenone, 2,2-dimethoxy-2-phenylacetophenone, and 2,2-dichloro-4-phenoxyacetophenone; 2,4,5-triarylimidazole dimers, including 2-(o-chlorophenyl)-4,5-diphenylimidazole dimer, 2-(o-chlorophenyl)-4,5-di-(m-methoxyphenyl imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, 2-(2,4-dimethoxyphenyl)-4,5-diphenylimidazole dimer and 2-(p-methylmercaptophenyl)-4,5-diphenylimidazole dimmer; combinations of these, or the like.

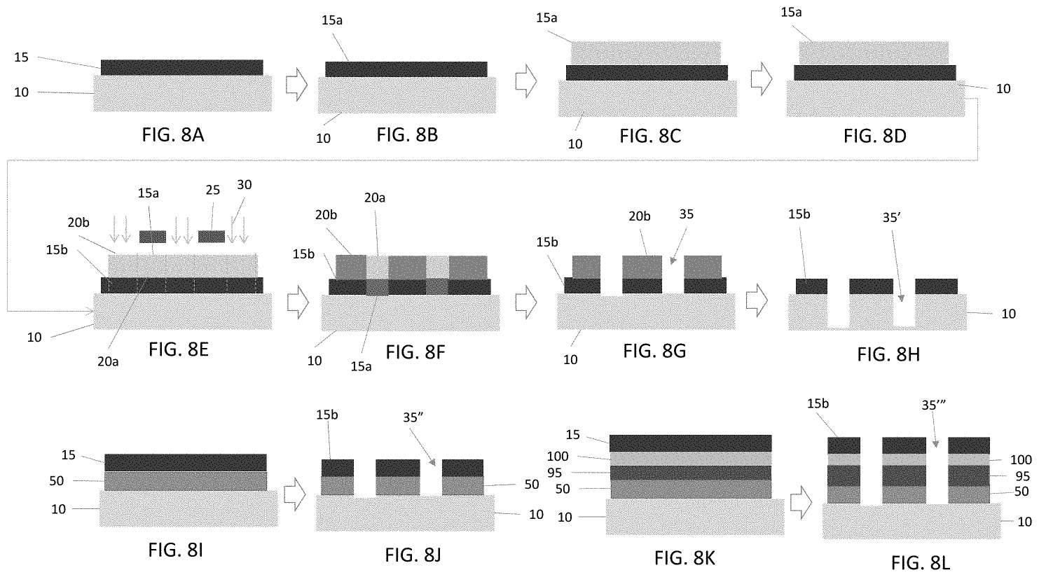

In some embodiments in which the PACs are photobase generators, the PACs includes quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like. Examples of photobase generators according to some embodiments of the disclosure are shown in FIG. 9.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, a cross-linking agent is added to the photoresist composition. The cross-linking agent reacts with one group from one of the hydrocarbon structures in the polymer resin and also reacts with a second group from a separate one of the hydrocarbon structures in order to cross-link and bond the two hydrocarbon structures together. This bonding and cross-linking increases the molecular weight of the polymer products of the cross-linking reaction and increases the overall linking density of the photoresist. Such an increase in density and linking density helps to improve the resist pattern.

In some embodiments the cross-linking agent has the following structure:

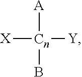

wherein C is carbon, n ranges from 1 to 15; A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B; a first terminal carbon C at a first end of a carbon C chain includes X and a second terminal carbon C at a second end of the carbon chain includes Y, wherein X and Y independently include an amine group, a thiol group, a hydroxyl group, an isopropyl alcohol group, or an isopropyl amine group, except when n=1 then X and Y are bonded to the same carbon C. Specific examples of materials that may be used as the cross-linking agent include the following:

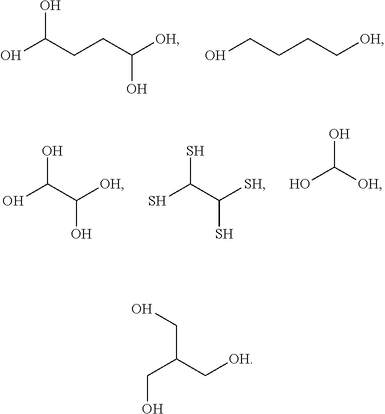

Alternatively, instead of or in addition to the cross-linking agent being added to the photoresist composition, a coupling reagent is added in some embodiments, in which the coupling reagent is added in addition to the cross-linking agent. The coupling reagent assists the cross-linking reaction by reacting with the groups on the hydrocarbon structure in the polymer resin before the cross-linking reagent, allowing for a reduction in the reaction energy of the cross-linking reaction and an increase in the rate of reaction. The bonded coupling reagent then reacts with the cross-linking agent, thereby coupling the cross-linking agent to the polymer resin.

Alternatively, in some embodiments in which the coupling reagent is added to the photoresist without the cross-linking agent, the coupling reagent is used to couple one group from one of the hydrocarbon structures in the polymer to a second group from a separate one of the hydrocarbon structures in order to cross-link and bond the two polymers together. However, in such an embodiment the coupling reagent, unlike the cross-linking agent, does not remain as part of the polymer, and only assists in bonding one hydrocarbon structure directly to another hydrocarbon structure.

In some embodiments, the coupling reagent has the following structure:

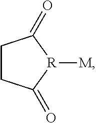

where R is a carbon atom, a nitrogen atom, a sulfur atom, or an oxygen atom; M includes a chlorine atom, a bromine atom, an iodine atom, —NO₂; —SO₃—; —H—; —CN; —NCO, —OCN; —CO₂—; —OH; —OR*, —OC(O)CR*; —SR, —SO₂N(R*)₂; —SO₂R*; SOR; —OC(O)R*; —C(O)OR*; —C(O)R*; —Si(OR*)₃; —Si(R*)₃; epoxy groups, or the like; and R* is a substituted or unsubstituted C1-C12 alkyl, C1-C12 aryl, C1-C12 aralkyl, or the like. Specific examples of materials used as the coupling reagent in some embodiments include the following:

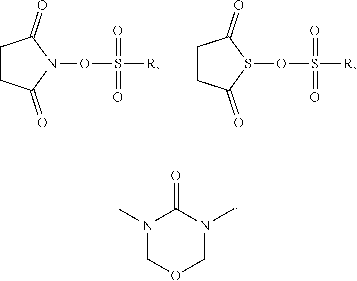

Some embodiments of the photoresist are metal-containing photoresists. In some embodiments, the metal-containing photoresist forms a metal-containing photoresist layer. The metals in the metal-containing photoresist includes one or more of Cs, Ba, La, Ce, In, Sn, or Ag in some embodiments.

In some embodiments, the metal-containing photoresist includes metal oxide nanoparticles. The metal oxides nanoparticles are selected from the group consisting of titanium dioxide, zinc oxide, zirconium dioxide, nickel oxide, cobalt oxide, manganese oxide, copper oxides, iron oxides, strontium titanate, tungsten oxides, vanadium oxides, chromium oxides, tin oxides, hafnium oxide, indium oxide, cadmium oxide, molybdenum oxide, tantalum oxides, niobium oxide, aluminum oxide, and combinations thereof in some embodiments. As used herein, nanoparticles are particles having an average particle size between 1 and 10 nm. In some embodiments, the metal oxide nanoparticles have an average particle size between 2 and 5 nm. In some embodiments, the amount of metal oxide nanoparticles in the photoresist composition ranges from about 1 wt. % to about 10 wt. % based on the total weight of the photoresist composition. In some embodiments, metal oxide nanoparticle concentrations below 1 wt. % provide photoresist layers that are too thin, and metal oxide nanoparticle concentrations greater than about 10 wt. % provide a photoresist composition that is too viscous and that will be difficult to provide a photoresist coating of uniform thickness on the substrate.

In some embodiments, the metal oxide nanoparticles are complexed with carboxylic acid or sulfonic acid ligands. For example, in some embodiments, zirconium oxide or hafnium oxide nanoparticles are complexed with methacrylic acid forming hafnium methacrylic acid (HfMAA) or zirconium methacrylic acid (ZrMAA). In some embodiments, the HfMAA or ZrMAA are dissolved at about a 5 wt. % to about 10 wt. % weight range in a coating solvent, such as propylene glycol methyl ether acetate (PGMEA). In some embodiments, the photoresist composition includes about 1 wt. % to about 10 wt. % of a photoactive compound (PAC) based on the total weight of the photoresist composition to form a metal oxide resist.

The individual components of the photoresist composition are placed into a solvent in order to aid in the mixing and dispensing of the photoresist. To aid in the mixing and dispensing of the photoresist, the solvent is chosen at least in part based upon the materials chosen for the polymers as well as the PAC. In some embodiments, the solvent is chosen such that the polymer resins and the PAC can be evenly dissolved into the solvent and dispensed upon the layer to be patterned.

In some embodiments, the solvent is an organic solvent, and includes one or more of any suitable solvent such as ketones, alcohols, polyalcohols, ethers, glycol ethers, cyclic ethers, aromatic hydrocarbons, esters, propionates, lactates, lactic esters, alkylene glycol monoalkyl ethers, alkyl lactates, alkyl alkoxypropionates, cyclic lactones, monoketone compounds that contain a ring, alkylene carbonates, alkyl alkoxyacetate, alkyl pyruvates, lactate esters, ethylene glycol alkyl ether acetates, diethylene glycols, propylene glycol alkyl ether acetates, alkylene glycol alkyl ether esters, alkylene glycol monoalkyl esters, or the like.

Specific examples of materials that may be used as the solvent for the photoresist under-layer composition include, acetone, methanol, ethanol, propanol, isopropanol (IPA), n-butanol, toluene, xylene, 4-hydroxy-4-methyl-2-pentatone, tetrahydrofuran (THF), methyl ethyl ketone, cyclohexanone (CHN), methyl isoamyl ketone, 2-heptanone (MAK), ethylene glycol, 1-ethoxy-2-propanol, methyl isobutyl carbinol (MIBC), ethylene glycol monoacetate, ethylene glycol dimethyl ether, ethylene glycol dimethyl ether, ethylene glycol methylethyl ether, ethylene glycol monoethyl ether, methyl cellosolve acetate, ethyl cellosolve acetate, diethylene glycol, diethylene glycol monoacetate, diethylene glycol monomethyl ether, diethylene glycol diethyl ether, diethylene glycol dimethyl ether, diethylene glycol ethylmethyl ether, diethethylene glycol monoethyl ether, diethylene glycol monobutyl ether, ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanate, methyl 3-methoxypropionate, ethyl 3-methoxypropionate, methyl 3-ethoxypropionate, ethyl 3-ethoxypropionate, methyl acetate, ethyl acetate, propyl acetate, n-butyl acetate (nBA), methyl lactate, ethyl lactate (EL), propyl lactate, butyl lactate, propylene glycol, propylene glycol monoacetate, propylene glycol monoethyl ether acetate, propylene glycol monomethyl ether acetate, propylene glycol monopropyl methyl ether acetate, propylene glycol monobutyl ether acetate, propylene glycol monobutyl ether acetate, propylene glycol monomethyl ether propionate, propylene glycol monoethyl ether propionate, propylene glycol methyl ether acetate, propylene glycol ethyl ether acetate, ethylene glycol monomethyl ether acetate, ethylene glycol monoethyl ether acetate, propylene glycol monomethyl ether, propylene glycol monoethyl ether, propylene glycol monopropyl ether, propylene glycol monobutyl ether, ethylene glycol monomethyl ether, ethylene glycol monoethyl ether, ethyl 3-ethoxypropionate, methyl 3-methoxypropionate, methyl 3-ethoxypropionate, and ethyl 3-methoxypropionate, β-propiolactone, β-butyrolactone, γ-butyrolactone (GBL), α-methyl-γ-butyrolactone, β-methyl-γ-butyrolactone, γ-valerolactone, γ-caprolactone, γ-octanoic lactone, α-hydroxy-γ-butyrolactone, 2-butanone, 3-methylbutanone, pinacolone, 2-pentanone, 3-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexene-2-one, 3-pentene-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, 3-methylcycloheptanone, propylene carbonate, vinylene carbonate, ethylene carbonate, butylene carbonate, acetate-2-methoxyethyl, acetate-2-ethoxyethyl, acetate-2-(2-ethoxyethoxy)ethyl, acetate-3-methoxy-3-methylbutyl, acetate-1-methoxy-2-propyl, dipropylene glycol, monomethylether, monoethylether, monopropylether, monobutylether, monophenylether, dipropylene glycol monoacetate, dioxane, methyl pyruvate, ethyl pyruvate, propyl pyruvate, methyl methoxypropionate, ethyl ethoxypropionate, n-methylpyrrolidone (NMP), 2-methoxyethyl ether (diglyme), ethylene glycol monomethyl ether, propylene glycol monomethyl ether, methyl propionate, ethyl propionate, ethyl ethoxy propionate, methylethyl ketone, cyclohexanone, 2-heptanone, cyclopentanone, cyclohexanone, ethyl 3-ethoxypropionate, propylene glycol methyl ether acetate (PGMEA), methylene cellosolve, 2-ethoxyethanol, N-methylformamide, N,N-dimethylformamide (DMF), N-methylformanilide, N-methylacetamide, N,N-dimethylacetamide, dimethylsulfoxide, benzyl ethyl ether, dihexyl ether, acetonylacetone, isophorone, caproic acid, caprylic acid, 1-octanol, 1-nonanol, benzyl alcohol, benzyl acetate, ethyl benzoate, diethyl oxalate, diethyl maleate, phenyl cellosolve acetate, or the like.

As one of ordinary skill in the art will recognize, the materials listed and described above as examples of materials that may be used for the solvent component of the photoresist composition are merely illustrative and are not intended to limit the embodiments. Rather, any suitable materials that dissolve the polymer and the photoacid generator may be used to help mix and apply the photoresist under-layer. All such materials are fully intended to be included within the scope of the embodiments.

In some embodiments, the method includes a second heating of the photoresist under-layer 15a and the photoresist layer 20 at a temperature of about 40° C. to about 140° C. for 10 seconds to 5 minutes after the photoresist layer 20 is disposed over the photoresist under-layer 15a, as shown in FIG. 1D. The second heating removes solvent from the photoresist layer. In some embodiments, the photoresist layer 20 and the photoresist under-layer 15 are heated at a temperature of about 60° C. to about 120° C. for 20 seconds to 3 minutes.

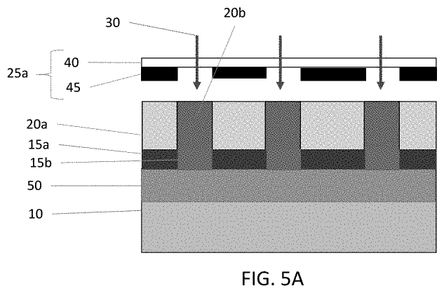

Then, as shown in FIG. 1E, a portion of the photoresist layer 20b is selectively exposed to actinic radiation 30. In some embodiments, a mask 25 is used to form exposed portions 20b and unexposed portions 20a of the photoresist layer, and exposed portions 15b and unexposed portions 15a of the photoresist under-layer. FIGS. 5A and 5B illustrate selective exposures of the photoresist layer 20 to form the exposed portions 20b and unexposed portions 20a. In some embodiments, the exposure to radiation is carried out by placing the photoresist-coated substrate in a photolithography tool. The photolithography tool includes a photomask 25a, 25b, optics, an exposure radiation source to provide the radiation 30/90 for exposure, and a movable stage for supporting and moving the substrate under the exposure radiation.

In some embodiments, the radiation source (not shown) supplies radiation 30/90, such as ultraviolet light, to the photoresist layer 20 in order to induce a reaction of the photoactive compounds in the photoresist, which in turn reacts with the polymer in the photoresist to chemically alter those regions of the photoresist layer 20b to which the radiation 30/90 impinges. In some embodiments, the radiation is electromagnetic radiation, such as g-line (wavelength of about 436 nm), i-line (wavelength of about 365 nm), ultraviolet radiation, far ultraviolet radiation, extreme ultraviolet, electron beams, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F₂ excimer laser light (wavelength of 157 nm), or a CO₂ laser-excited Sn plasma (extreme ultraviolet, wavelength of 13.5 nm).

In some embodiments, optics (not shown) are used in the photolithography tool to expand, reflect, or otherwise control the radiation before or after the radiation 30/90 is patterned by the photomask 25a/25b. In some embodiments, the optics include one or more lenses, mirrors, filters, and combinations thereof to control the radiation 30/90 along its path.

In an embodiment, the patterned radiation 30/90 is extreme ultraviolet light having a 13.5 nm wavelength, the photoactive compound (PAC) is a photoacid generator, the group to be decomposed is an ALG pendant to the hydrocarbon main chain structure of the polymer. In some embodiments, a cross linking agent is used. The patterned radiation 30/90 impinges upon the photoacid generator and the photoacid generator absorbs the impinging patterned radiation 30/90. This absorption initiates the photoacid generator to generate a proton (e.g., a H⁺ atom) within the photoresist layer 20b and the photoresist under-layer 15b. When the proton impacts the ALG on the hydrocarbon structure, the proton reacts with the ALG, chemically altering the ALG and altering the properties of the polymer in general. The acid generated by the photoacid generator in the photoresist under-layer 15 cleaves the ALG on polymer with the pendant ALG, thereby increasing the polymer's solubility in the developer.

In some embodiments, the acids generated during the exposure to actinic radiation cleave ALGs on the cross-linked polymers in the photoresist under-layer 15b causing the polymers in the photoresist under-layer to de-crosslink, and increasing the solubility of the photoresist under-layer 15b in a subsequently applied developer solution. For example, as shown in FIG. 3A, in some embodiments, the ALG and the crosslinking group are on the same pendant side chain of the polymer. The cleaving of the ALG in this embodiment de-crosslinks the crosslinked polymers.

As shown in FIG. 5A, the exposure radiation 30 passes through a photomask 25a before irradiating the photoresist layer 20 in some embodiments. In some embodiments, the photomask has a pattern to be replicated in the photoresist layer 20. The pattern is formed by an opaque pattern 45 on the photomask substrate 40, in some embodiments. The opaque pattern 45 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 20 and photoresist under-layer to form exposed regions 15b, 20b and unexposed regions 15a, 20a is performed using extreme ultraviolet lithography. In an extreme ultraviolet lithography operation a reflective photomask 25b is used to form the patterned exposure light, as shown in FIG. 5B. The reflective photomask 25b includes a low thermal expansion glass substrate 55, on which a reflective multilayer 60 of Si and Mo is formed. A capping layer 70 and absorber layer 75 are formed on the reflective multilayer 60. A rear conductive layer 80 is formed on the backside of the low thermal expansion substrate 55. In extreme ultraviolet lithography, extreme ultraviolet radiation 85 is directed towards the reflective photomask 25b at an incident angle of about 6°. A portion 90 of the extreme ultraviolet radiation is reflected by the Si/Mo multilayer 55 towards the photoresist-coated substrate 10, while the portion of the extreme ultraviolet radiation incident upon the absorber layer 75 is absorbed by the photomask. In some embodiments, additional optics, including mirrors, are between the reflective photomask 25b and the photoresist-coated substrate.

In some embodiments, the exposure of the photoresist layer 20 uses an immersion lithography technique. In such a technique, an immersion medium (not shown) is placed between the final optics and the photoresist layer 20, and the exposure radiation 30 passes through the immersion medium.

As a result of the operation in FIG. 1E, a latent pattern is formed in the resist layer 20. The latent pattern of the photoresist layer refers to the exposed pattern in the photoresist layer 20, which eventually becomes a physical resist pattern, such as by a developing operation. The latent pattern of the resist layer 20 includes unexposed portions 20a and exposed portions 20b. In an embodiment using a chemically amplified (CA) resist material with a PAG, acids are generated in the exposed portions 20b during the exposure process. In the latent pattern, the exposed portions 20b, 15b of the photoresist layer 20 and photoresist under-layer 15 are physically or chemically changed. In some examples, the exposed portions 20b, 15b are de-protected, inducing polarity change for dual-tone imaging (developing).

The selectively exposed photoresist layer 20 and photoresist under-layer 15 are then subjected to a third heating in some embodiments, as shown in FIG. 1F. A third heating of the photoresist under-layer and the selectively exposed photoresist layer, also known as a post-exposure baking (PEB) operation, is performed at a temperature of about 100° C. to about 200° C. for about 10 seconds to about 10 minutes. During the PEB operation, more acid is generated in the exposed portions 20b, 15b of the photoresist layer and the photoresist under-layer. The generated acid furthers the chemical changes in the photoresist layer and photoresist under-layer. In some embodiments, the PEB heating temperature is in a range of about 130° C. to about 170° C. for about 30 seconds to about 5 minutes.

Development is subsequently performed, as shown in FIG. 1G, using a solvent, to form a pattern 35 in the photoresist layer and photoresist under-layer. In some embodiments where positive tone development is desired, a positive tone developer such as a basic aqueous solution is used to remove the radiation exposed regions 20b, 15b of the photoresist layer and photoresist under-layer. In some embodiments, the positive tone developer includes one or more selected from tetramethylammonium hydroxide (TMAH), tetrabutylammonium hydroxide, sodium hydroxide, potassium hydroxide, sodium carbonate, sodium bicarbonate, sodium silicate, sodium metasilicate, aqueous ammonia, monomethylamine, dimethylamine, trimethylamine, monoethylamine, diethylamine, triethylamine, monoisopropylamine, diisopropylamine, triisopropylamine, monobutylamine, dibutylamine, monoethanolamine, diethanolamine, triethanolamine, dimethylaminoethanol, diethylaminoethanol, ammonia, caustic soda, caustic potash, sodium metasilicate, potassium metasilicate, sodium carbonate, tetraethylammonium hydroxide, combinations of these, or the like.

In some embodiments, the developer is applied to the photoresist layer using a spin-on process. In the spin-on process, the developer is applied to the photoresist layer by a dispenser from above while the coated substrate is rotated. The developer is selected so that it removes the exposed portions 20b, 15b of the photoresist layer and the photoresist under-layer in some embodiments. In some embodiments, the developer is supplied at a rate of between about 5 ml/min and about 800 ml/min, while the coated substrate is rotated at a speed of between about 100 rpm and about 2000 rpm. In some embodiments, the developer is at a temperature of between about 10° C. and about 80° C. The development operation continues for between about 30 seconds to about 10 minutes in some embodiments.

While the spin-on operation is one suitable method for developing the photoresist layer and photoresist under-layer after exposure, it is intended to be illustrative and is not intended to limit the embodiment. Rather, any suitable development operations, including dip processes, puddle processes, and spray-on methods, may alternatively be used. All such development operations are included within the scope of the embodiments.

In some embodiments, the high solubility of the exposed portions 15b of the photoresist under-layer in the developer due to the de-crosslinking caused by the cleaving of the ALG provides improved resolution of the photoresist patterns because photoresist residue and scum on the photoresist under-layer is removed along with the underlying photoresist under-layer during the developing operation.

Additional processing is performed while the patterned photoresist layer is in place in some embodiments. For example, an etching operation, using dry or wet etching, is performed in some embodiments, to transfer the pattern 35 of the photoresist layer to the substrate 10, thereby forming pattern 35′ in the substrate. The remaining photoresist layer is subsequently removed by a suitable photoresist stripping or photoresist ashing operation, as shown in FIG. 1H. In some embodiments, the portion 15a of the photoresist under-layer not exposed to actinic radiation remains on the substrate 10, as shown in FIG. 1H. In other embodiments, the unexposed portions 15a of the photoresist under-layer are removed during the photoresist stripping, photoresist ashing, or substrate etching operation.

FIGS. 1I and 1J are cross sectional views of an alternative embodiment of manufacturing a semiconductor device according to the disclosure. FIG. 1I illustrates a semiconductor substrate 10 with a layer to be patterned 50 disposed thereon, and the photoresist under-layer 15 disposed over the layer to be patterned 50. In some embodiments, the layer to be patterned 50 is a hard mask layer; metallization layer; or a dielectric layer, such as a passivation layer, disposed over a metallization layer. In embodiments where the layer to be patterned 50 is a metallization layer, the layer to be patterned 50 is formed of a conductive material using metallization processes, and metal deposition techniques, including chemical vapor deposition, atomic layer deposition, and physical vapor deposition (sputtering). Likewise, if the layer to be patterned 50 is a dielectric layer, the layer to be patterned 50 is formed by dielectric layer formation techniques, including thermal oxidation, chemical vapor deposition, atomic layer deposition, and physical vapor deposition. The substrate 10 with the layer to be patterned 50 disposed thereon, is subsequently processed in a similar manner as discussed herein with reference to FIGS. 1A to 1G, and the layer to be patterned 50 is etched using the photoresist pattern 35 as an etch mask to form a pattern 35″ in the layer to be patterned 50, as shown in FIG. 1J. The layer to be patterned 50 may be etched by wet or dry etching depending on the materials to be etched and the desired configuration of the pattern 35″.

FIGS. 1K and 1L are cross sectional views of an alternative embodiment of manufacturing a semiconductor device according to the disclosure. FIG. 1K illustrates a mid-layer 100 and bottom layer 95 of a tri-layer resist disposed over the substrate 10. A layer to patterned 50, as discussed above, is disposed over the substrate 10 in some embodiments.

A tri-layer photoresist includes a bottom layer, a middle layer, and a top layer. In some embodiments, the top layer is the photoresist layer 20. In some embodiments, the photoresist under-layer 15 of the present disclosure is disposed over the mid-layer 100 of the tri-layer resist, as shown in FIG. 1K, and the photoresist layer 20 is subsequently formed over the photoresist under-layer 15 (see FIG. 1C).

In some embodiments, the bottom layer 95 is an organic material having a substantially planar upper surface, and the middle layer 100 is an anti-reflective layer. In some embodiments, the organic material of the bottom layer 95 includes a plurality of monomers or polymers that are not cross-linked. In some embodiments, the bottom layer 95 contains a material that is patternable and/or has a composition tuned to provide anti-reflection properties. Exemplary materials for the bottom layer 95 include carbon backbone polymers. The bottom layer 95 is used to planarize the structure, as the underlying structure may be uneven depending on the structure of devices in an underlying device layer. In some embodiments, the bottom layer 95 is formed by a spin coating process. In certain embodiments, the thickness of the bottom layer 95 ranges from about 50 nm to about 500 nm.

The middle layer 100 of the trilayer resist structure may have a composition that provides anti-reflective properties for the photolithography operation and/or hard mask properties. In some embodiments, the middle layer 100 includes a silicon containing layer (e.g., a silicon hard mask material). The middle layer 100 may include a silicon-containing inorganic polymer. In other embodiments, the middle layer 100 includes a siloxane polymer. In other embodiments, the middle layer 100 includes silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials. The middle layer 100 may be bonded to adjacent layers, such as by covalent bonding, hydrogen bonding, or hydrophilic-to-hydrophilic forces.

The structure of FIG. 1K is subsequently processed in a similar manner as discussed herein with reference to FIGS. 1A to 1J, and the optional layer to be patterned 50, and the middle layer 100 and bottom layer 95 are etched using the photoresist pattern 35 as an etch mask to form a pattern 35′″, as shown in FIG. 1L. The middle layer 100, and bottom layer 95 may be etched by wet or dry etching depending on the materials to be etched and the desired configuration of the pattern 35′″. In some embodiments, the pattern 35′″ in the middle layer 100 and bottom layer 95 is extended into the substrate 10 or the optional layer to be patterned 50 using suitable wet or dry etching operations.

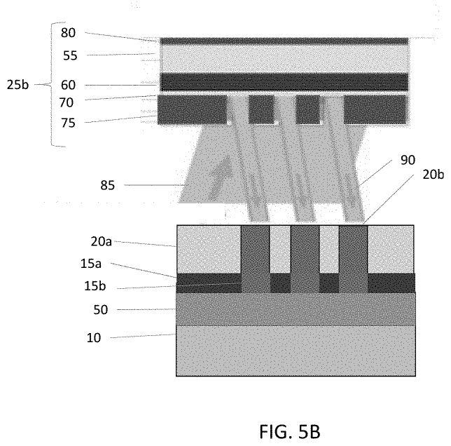

FIGS. 6A-6H are cross sectional views of sequential operations for manufacturing a semiconductor device according to an embodiment of the disclosure. FIG. 6A shows a photoresist under-layer 15 formed over a substrate 10, such as a wafer. The photoresist under-layer 15 is formed over the substrate 10 in the same manner as disclosed herein in reference to FIG. 1A.

In some embodiments, the photoresist under-layer 15 includes a photoresist under-layer composition including a polymer having pendant acid labile groups (ALG), a polymer having pendant carboxylic acid groups, an acid generator, and a solvent. In some embodiments, the acid generator is a thermal acid generator. In some embodiments, the photoresist under-layer 15 does not include a polymer with a crosslinking group.

In some embodiments, the pendant acid-labile groups are about 20 wt. % to about 80 wt. % of the polymer having pendant acid-labile groups. In some embodiments, the pendant carboxylic acid groups are about 5 wt. % to about 30 wt. % of the polymer having pendant acid-labile groups. If the amount of pendant carboxylic acid groups is less than about 5 wt. % the photoresist under-layer may have insufficient beneficial effects. If the amount of the pendant carboxylic acid groups is greater than about 30 wt. % the polymer having pendant carboxylic acid groups may lack sufficient solubility in the solvent. In some embodiments, the pendant acid-labile groups are about 30 wt. % to about 70 wt. % of the polymer having pendant acid-labile groups, and the carboxylic acid groups are about 10 wt. % to about 20 wt. % of the polymer having the carboxylic acid groups. In some embodiments, the pendant ALG and carboxylic acid groups are on the same polymer.

In some embodiments, the acid labile group is connected to the polymer having the pendant acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group.

In some embodiments, the base polymer having pendant ALG or pendant carboxylic acid groups are any of the polymers disclosed in reference to FIG. 1B. In some embodiments, the polymer main chain having the pendant ALG or carboxylic acid group is a hydrocarbon chain. In some embodiments, the polymer is a polyhydroxystyrene, polyacrylate, or polymethylmethacrylate based polymer.

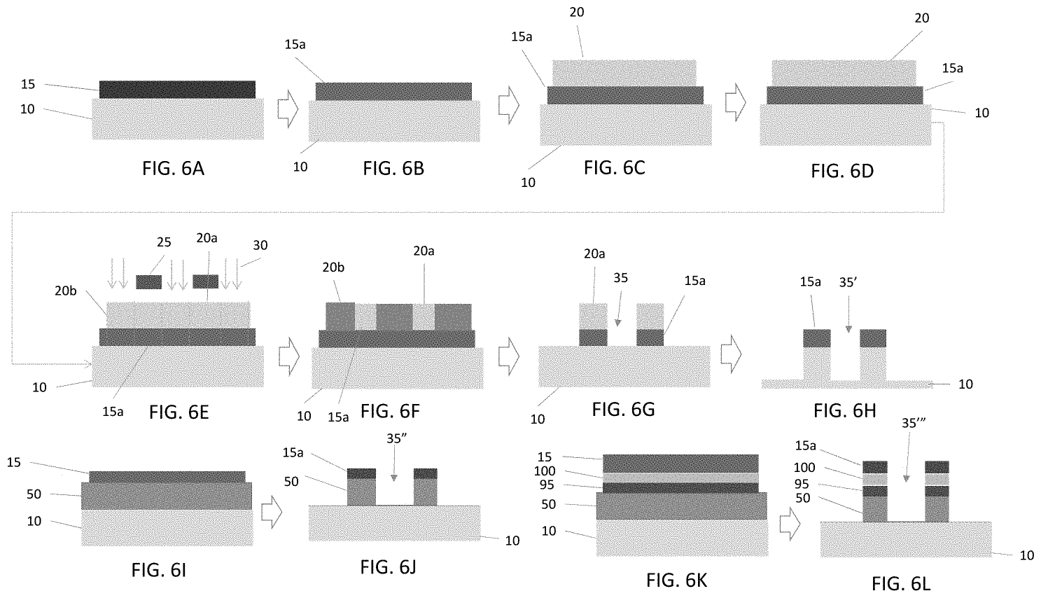

In some embodiments, the acid generator is a thermal acid generator (TAG). In some embodiments, the TAG is any one of the TAGs shown in FIG. 7. In some embodiments, the TAG is selected from NH₄⁺C₄F₉SO₃⁻ and NH₄⁺CF₃SO₃⁻. In some embodiments, the concentration of the thermal acid generator ranges from about 5 wt. % to about 40 wt. % based on the total weight of the thermal acid generator and the polymers in the photoresist under-layer. In other embodiments, the concentration of the thermal acid generator ranges from about 10 wt. % to about 25 wt. % based on the total weight of the thermal acid generator and the polymers in the photoresist under-layer.

The photoresist under-layer 15 is subsequently heated to remove the solvent and trigger the thermal acid generator (TAG) to release acid. The TAG is selected such that temperature to release the acid is close to the curing temperature of the photoresist under layer. In some embodiments, the photoresist under-layer 15 is subjected to a first heating at a temperature of about 140° C. to about 200° C. for 10 seconds to 5 minutes to form a cross-linked photoresist under-layer composition 15a, as shown in FIG. 6B. In some embodiments, the first heating is performed at a temperature of about 150° C. to about 190° C. for about 20 seconds to about 3 minutes. In other embodiments, the first heating is performed at a temperature of about 160° C. to about 180° C. for about 30 seconds to about 2 minutes.

The first heating of the photoresist under-layer 15 generates the acid from the thermal acid generator and the generated acid reacts with the ALG on the polymer having the ALG in accordance with the ALG de-protect reaction, as shown in FIG. 2C, thereby increasing the solubility of the photoresist under-layer in the photoresist developer.

A photoresist composition is subsequently disposed over the substrate 10 to form a photoresist layer 20, as shown in FIG. 6C. The photoresist layer 20 is formed in a similar manner as disclosed herein with respect to FIG. 1C.

In some embodiments, the method includes a second heating of the photoresist under-layer 15a and the photoresist layer 20 at a temperature of about 40° C. to about 140° C. for about 10 seconds to about 5 minutes after the photoresist layer 20 is disposed over the photoresist under-layer 15a, as shown in FIG. 6D. The second heating removes solvent from the photoresist layer. In some embodiments, the photoresist layer 20 and the photoresist under-layer 15 are heated at a temperature of about 60° C. to about 120° C. for about 20 seconds to about 3 minutes.

Then, as shown in FIG. 6E, a portion of the photoresist layer 20b is selectively exposed to actinic radiation 30. In some embodiments, a mask 25 is used to form the exposed portions 20b and unexposed portions 20a of the photoresist layer, and the exposed portions 15b and unexposed portions 15a of the photoresist under-layer. In some embodiments, the exposure to actinic radiation is performed in the manner disclosed with reference to FIG. 1E.

The selectively exposed photoresist layer 20 and photoresist under-layer 15 are then subjected to a third heating or post-exposure baking (PEB) operation in some embodiments, as shown in FIG. 6F. The PEB is performed at a temperature of about 100° C. to about 200° C. for about 10 seconds to about 10 minutes. During the PEB operation, more acid may be generated in the exposed portions 20b, 15b of the photoresist layer and the photoresist under-layer. The generated acid furthers the chemical changes in the photoresist layer and photoresist under-layer. In some embodiments, the PEB heating temperature is in a range of about 130° C. to about 170° C. for about 30 seconds to about 5 minutes.

Development is subsequently performed, as shown in FIG. 6G, using a solvent, to form a pattern 35 in the photoresist layer and photoresist under-layer. The development operation is performed in the same manner as disclosed herein in reference to FIG. 1G in some embodiments. The cross-linked unexposed portion 15a of the photoresist under-layer is resistant to being removed during the development operation.

Additional processing is performed while the patterned photoresist layer is in place in some embodiments. For example, an etching operation, using dry or wet etching, is performed in some embodiments, to transfer the pattern 35 of the photoresist layer to the substrate 10, thereby forming the pattern 35′ in the substrate, as shown in FIG. 6H. As explained with reference to FIG. 1H, the remaining photoresist layer is subsequently removed by a suitable photoresist stripping or photoresist ashing operation, as shown in FIG. 1H. In some embodiments, the portion 15a of the photoresist under-layer not exposed to actinic radiation remains on the substrate 10. In other embodiments, the unexposed portions 15a of the photoresist under-layer are removed during the photoresist stripping, photoresist ashing, or substrate etching operation.

FIGS. 6I and 6J are cross sectional views of an alternative embodiment of manufacturing a semiconductor device according to the disclosure. FIG. 6I illustrates a semiconductor substrate 10 with a layer to be patterned 50 disposed thereon, and the photoresist under-layer 15 disposed over the layer to be patterned 50. In some embodiments, the layer to be patterned 50 is a hard mask layer; metallization layer; or a dielectric layer, such as a passivation layer, disposed over a metallization layer. In some embodiments, the structure illustrated in FIG. 6I is processed in the same manner as disclosed with reference to FIGS. 6A and 6H to provide the structure of FIG. 6J.

FIGS. 6K and 6L are cross sectional views of an alternative embodiment of manufacturing a semiconductor device according to the disclosure. FIG. 6K illustrates a mid-layer 100 and bottom layer 95 of a tri-layer resist disposed over the substrate 10. A layer to be patterned 50, as discussed above, is disposed over the substrate 10 in some embodiments. In some embodiments, the structure illustrated in FIG. 6K is processed in the same manner as disclosed with reference to FIGS. 6A and 6J to provide the structure of FIG. 6L.

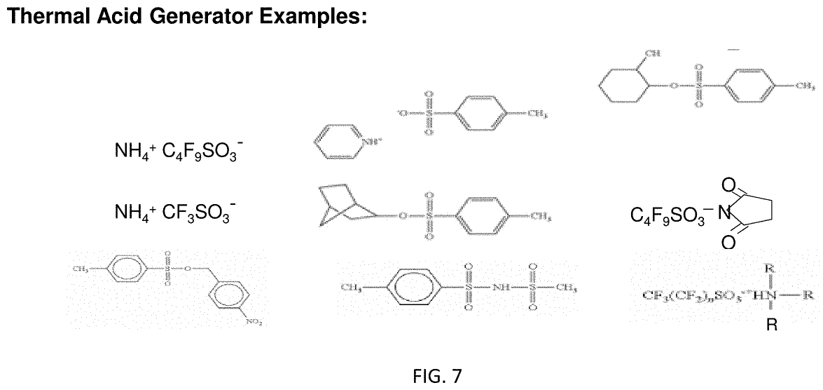

FIGS. 8A-8H are cross sectional views of sequential operations for manufacturing a semiconductor device according to an embodiment of the disclosure. FIG. 8A shows a photoresist under-layer 15 formed over a substrate 10, such as a wafer. The photoresist under-layer 15 is formed over the substrate 10 in the same manner as disclosed herein in reference to FIGS. 1A and 6A.

In some embodiments, the photoresist under-layer 15 includes a photoresist under-layer composition including a polymer having pendant acid labile groups (ALG), a polymer having pendant crosslinking groups, an acid generator, a base generator, and a solvent. In some embodiments, the acid generator is a thermal acid generator, and in some embodiments, the base generator is a photobase generator.

In some embodiments, the pendant acid-labile groups are about 20 wt. % to about 60 wt. % of the polymer having pendant acid-labile groups. In some embodiments, the pendant crosslinking groups are about 20 wt. % to about 60 wt. % of the polymer having pendant crosslinking groups. In some embodiments, the pendant acid-labile groups are about 30 wt. % to about 50 wt. % of the polymer having pendant acid-labile groups, and the crosslinking groups are about 30 wt. % to about 50 wt. % of the polymer having the crosslinking groups. In some embodiments, the pendant ALG and crosslinking groups are on the same polymer.

In some embodiments, the acid labile group is connected to the polymer having the pendant acid labile groups is connected to the polymer having acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In some embodiments, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group.

In some embodiments, the base polymer having pendant ALG or pendant crosslinking groups are any of the polymers disclosed in reference to FIG. 1B. In some embodiments, the polymer main chain having the pendant ALG or crosslinking group is a hydrocarbon chain. In some embodiments, the polymer is a polyhydroxystyrene, polyacrylate, or a polymethylmethacrylate based polymer.

In some embodiments, the acid generator is a thermal acid generator (TAG). In some embodiments, the TAG is any one of the TAGs shown in FIG. 7. In some embodiments, the TAG is selected from NH₄⁺C₄F₉SO₃⁻ and NH₄⁺CF₃SO₃⁻. In some embodiments, the concentration of the thermal acid generator ranges from about 5 wt. % to about 40 wt. % based on the total weight of the thermal acid generator and the polymers in the photoresist under-layer. In other embodiments, the concentration of the thermal acid generator ranges from about 10 wt. % to about 25 wt. % based on the total weight of the thermal acid generator and the polymers in the photoresist under-layer.

In some embodiments the photobase generators include quaternary ammonium dithiocarbamates, a aminoketones, oxime-urethane containing molecules such as dibenzophenoneoxime hexamethylene diurethan, ammonium tetraorganylborate salts, and N-(2-nitrobenzyloxycarbonyl)cyclic amines, combinations of these, or the like. Examples of photobase generators according to some embodiments of the disclosure are shown in FIG. 9. In some embodiments, the concentration of the photobase generator ranges from about 5 wt. % to about 40 wt. % based on the total weight of the photobase generator and the polymers in the photoresist under-layer. If the concentration of the photobase generator is less than about 5 wt. % the photoresist under-layer may have insufficient beneficial effects. If the amount of the photobase generator is greater than about 40 wt. % the cost of the photoresist under-layer material composition may become excessive with no significant improvement in beneficial properties of photoresist under-layer. In other embodiments, the concentration of the photobase generator ranges from about 10 wt. % to about 25 wt. % based on the total weight of the photobase generator and the polymers in the photoresist under-layer.

In some embodiments, the solvent in the photoresist under-layer composition is any of the same solvent disclosed herein in reference to FIG. 1A.

The photoresist under-layer 15 is subsequently heated to cure the under-layer, remove the solvent, and cause the polymers with crosslinking groups to crosslink. In some embodiments, the photoresist under-layer 15 is subjected to a first heating at a temperature of about 40° C. to about 140° C. for about 10 seconds to about 5 minutes to form a cross-linked photoresist under-layer composition 15a, as shown in FIG. 8B. The heating causes the crosslinking groups to cross-link. In some embodiments, the first heating is performed at a temperature of about 60° C. to about 130° C. for about 20 seconds to about 3 minutes. In other embodiments, the first heating is performed at a temperature of about 80° C. to about 120° C. for about 30 seconds to about 2 minutes.

A photoresist composition is subsequently disposed over the substrate 10 to form a photoresist layer 20, as shown in FIG. 8C. The photoresist layer 20 is formed of the same components and in a similar manner as disclosed herein with respect to FIG. 1C.

In some embodiments, the method includes a second heating of the photoresist under-layer 15a and the photoresist layer 20 at a temperature of about 40° C. to about 140° C. for about 10 seconds to about 5 minutes after the photoresist layer 20 is disposed over the photoresist under-layer 15a, as shown in FIG. 8D. The second heating removes solvent from the photoresist layer. In some embodiments, the photoresist layer 20 and the photoresist under-layer 15 are heated at a temperature of about 60° C. to about 120° C. for about 20 seconds to about 3 minutes.

Then, as shown in FIG. 8E, a portion of the photoresist layer 20b is selectively exposed to actinic radiation 30. In some embodiments, a mask 25 is used to form exposed portions 20b and unexposed portions 20a of the photoresist layer, and exposed portions 15b and unexposed portions 15a of the photoresist under-layer. In some embodiments, the exposure to actinic radiation is performed in the manner as disclosed with reference to FIGS. 1E and 6E. The actinic radiation exposure causes the photobase generator to generate a base in the portions 15b of the photoresist under-layer exposed to actinic radiation.

The selectively exposed photoresist layer 20 and photoresist under-layer 15 are then subjected to a third heating or post-exposure baking (PEB) operation in some embodiments, as shown in FIG. 8F. The PEB is performed at a temperature of about 140° C. to about 200° C. for about 10 seconds to about 10 minutes. During the PEB operation, the TAG is triggered to generate acid in the photoresist under-layer, and more acid may be generated in the exposed portions 20b of the photoresist layer. The acid generated by the TAG in the photoresist under-layer 15 cleaves the ALG on polymer with the pendant ALG, thereby increasing the polymer's solubility in the developer.

In some embodiments, the acids generated by the TAG cleave ALGs on the cross-linked polymers in the photoresist under-layer 15b causing the polymers in the photoresist under-layer to de-crosslink, and increasing the solubility of the photoresist under-layer 15b in a subsequently applied developer solution. For example, as shown in FIG. 3A, in some embodiments, the ALG and the crosslinking group are on the same pendant side chain of the polymer. The cleaving of the ALG in this embodiment de-crosslinks the crosslinked polymers.

is neutralized by the base generated by the photobase generator in some embodiments. The generated acid furthers the chemical changes, such as the ALG de-protect reaction illustrated in FIG. 2C in the photoresist layer and photoresist under-layer. In some embodiments, the PEB heating temperature is in a range of about 150° C. to about 180° C. for about 30 seconds to about 5 minutes.

Development is subsequently performed, as shown in FIG. 8G, using a solvent, to form a pattern 35 in the photoresist layer and photoresist under-layer. The development operation is performed in a similar manner as disclosed herein in reference to FIG. 1G in some embodiments. In some embodiments where negative tone development is desired, an organic solvent or critical fluid is used to remove the unexposed portions 20a of the photoresist. In some embodiments, the negative tone developer includes one or more selected from hexane, heptane, octane, toluene, xylene, dichloromethane, chloroform, carbon tetrachloride, trichloroethylene, and like hydrocarbon solvents; critical carbon dioxide, methanol, ethanol, propanol, butanol, and like alcohol solvents; diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether and like ether solvents; acetone, methyl ethyl ketone, methyl isobutyl ketone, isophorone, cyclohexanone and like ketone solvents; methyl acetate, ethyl acetate, propyl acetate, butyl acetate and like ester solvents; pyridine, formamide, and N,N-dimethyl formamide or the like.

Additional processing is performed while the patterned photoresist layer is in place in some embodiments. For example, an etching operation, using dry or wet etching, is performed in some embodiments, to transfer the pattern 35 of the photoresist layer to the substrate 10, thereby forming pattern 35′ in the substrate, as shown in FIG. 8H. As explained with reference to FIGS. 1H and 6H, the remaining photoresist layer is subsequently removed by a suitable photoresist stripping or photoresist ashing operation, as shown in FIG. 8H. In some embodiments, the portion 15b of the photoresist under-layer exposed to actinic radiation remains on the substrate 10. In other embodiments, the exposed portions 15b of the photoresist under-layer are removed during the photoresist stripping, photoresist ashing, or substrate etching operation.

FIGS. 8I and 8J are cross sectional views of an alternative embodiment of manufacturing a semiconductor device according to the disclosure. FIG. 8I illustrates a semiconductor substrate 10 with a layer to be patterned 50 disposed thereon, and the photoresist under-layer 15 disposed over the layer to be patterned 50. In some embodiments, the layer to be patterned 50 is a hard mask layer; metallization layer; or a dielectric layer, such as a passivation layer, disposed over a metallization layer. In some embodiments, the structure illustrated in FIG. 8I is processed in the same manner as disclosed with reference to FIGS. 8A and 8H to provide the structure of FIG. 8J.

FIGS. 8K and 8L are cross sectional views of an alternative embodiment of manufacturing a semiconductor device according to the disclosure. FIG. 8K illustrates a mid-layer 100 and bottom layer 95 of a tri-layer resist disposed over the substrate 10. A layer to be patterned 50, as discussed above, is disposed over the substrate 10 in some embodiments. In some embodiments, the structure illustrated in FIG. 8K is processed in the same manner as disclosed with reference to FIGS. 8A and 8J to provide the structure of FIG. 8L.

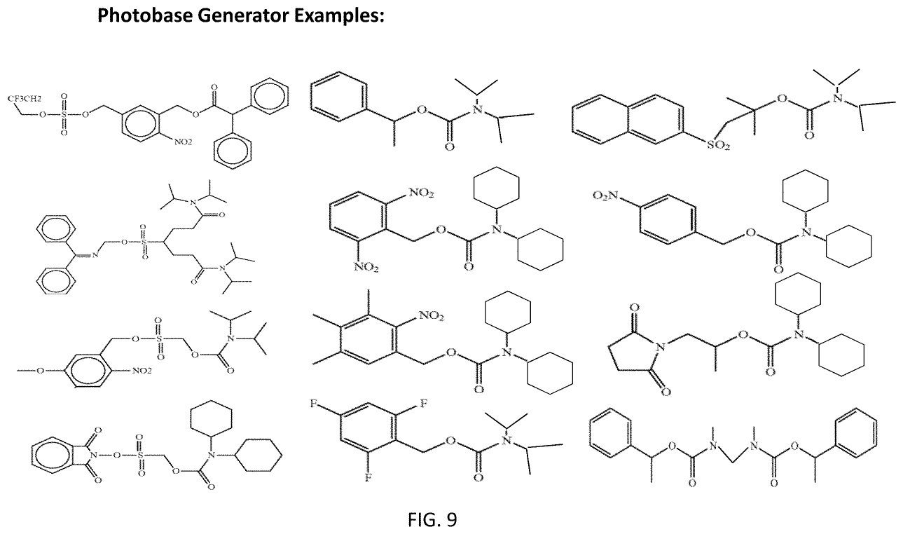

FIGS. 10A-10H are cross sectional views of sequential operations for manufacturing a semiconductor device according to an embodiment of the disclosure. FIG. 10A shows a photoresist under-layer 15 formed over a substrate 10, such as a wafer. The photoresist under-layer 15 is formed over the substrate 10 in the same manner as disclosed herein in reference to FIGS. 1A, 6A, and 8A.

In some embodiments, the photoresist under-layer 15 includes a photoresist under-layer composition including a polymer having pendant carboxylic acid groups, an acid generator, a base generator, an alcohol, and a solvent. In some embodiments, the acid generator is a thermal acid generator, and in some embodiments, the base generator is a photobase generator. In some embodiments, the solvent in the photoresist under-layer composition is the same solvent disclosed herein in reference to FIG. 1A.

In some embodiments, the pendant carboxylic acid groups are about 10 wt. % to about 60 wt. % of the polymer having pendant carboxylic acid groups. In some embodiments, the pendant carboxylic acid groups are about 20 wt. % to about 50 wt. % of the polymer having pendant carboxylic acid groups, and the pendant carboxylic acid groups are about 30 wt. % to about 40 wt. % of the polymer having the pendant carboxylic acid groups in other embodiments.

In some embodiments, the base polymer having pendant carboxylic acid groups are any of the polymers disclosed in reference to FIG. 1B. In some embodiments, the polymer main chain having the pendant carboxylic acid groups is a hydrocarbon chain. In some embodiments, the polymer is a polyhydroxystyrene, polyacrylate, or polymethylmethacrylate based polymer.

In some embodiments, the acid generator is a thermal acid generator (TAG). In some embodiments, the TAG is any one of the TAGs shown in FIG. 7. In some embodiments, the TAG is selected from NH₄⁺C₄F₉SO₃⁻ and NH₄⁺CF₃SO₃⁻. In some embodiments, the concentration of the thermal acid generator ranges from about 5 wt. % to about 40 wt. % based on the total weight of the thermal acid generator and the polymer in the photoresist under-layer. In other embodiments, the concentration of the thermal acid generator ranges from about 10 wt. % to about 25 wt. % based on the total weight of the thermal acid generator and the polymer in the photoresist under-layer.

In some embodiments, the base generator is a photobase generator. The photobase generator is one or more of the photobase generators disclosed with respect to FIG. 8A and disclosed in FIG. 9 in some embodiments. In some embodiments, the concentration of the photobase generator ranges from about 5 wt. % to about 40 wt. % based on the total weight of the photobase generator and the polymer in the photoresist under-layer. In other embodiments, the concentration of the photobase generator ranges from about 10 wt. % to about 25 wt. % based on the total weight of the photobase generator and the polymer in the photoresist under-layer.

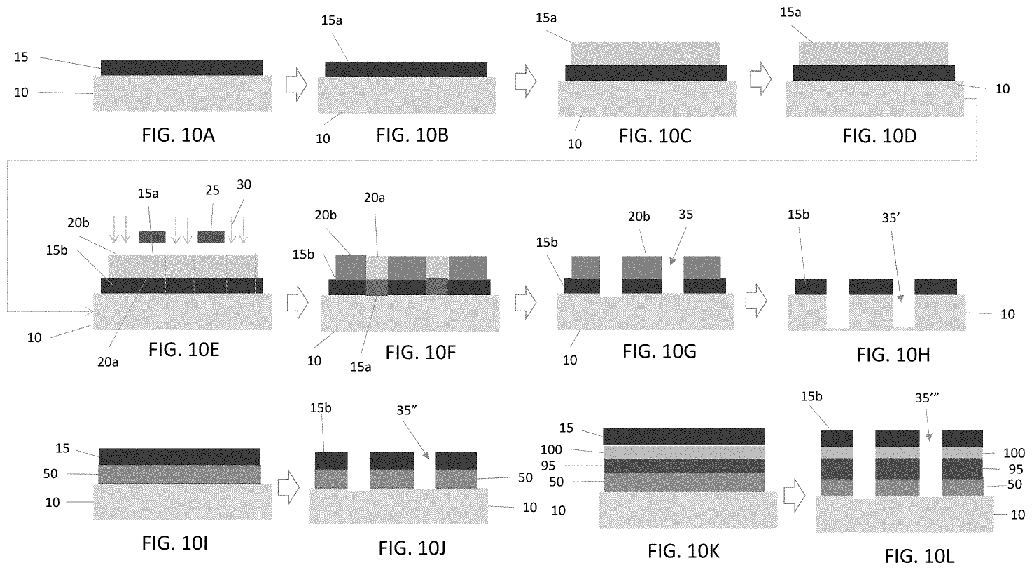

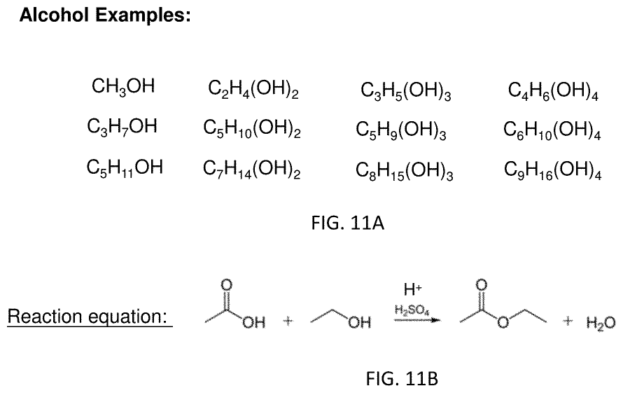

In some embodiments, the alcohol is one or more of any of the alcohols shown in FIG. 11. In some embodiments, the concentration of the alcohol ranges from about 5 wt. % to about 40 wt. % based on the total weight of the alcohol and the polymer in the photoresist under-layer. In other embodiments, the concentration of the alcohol ranges from about 10 wt. % to about 25 wt. % based on the total weight of the alcohol and the polymer in the photoresist under-layer.

The photoresist under-layer 15 is subsequently heated to cure the under-layer and remove the solvent. The curing temperature of the photoresist under-layer is selected so that it is below the temperature that triggers the thermal acid generator to generate acid. In some embodiments, the photoresist under-layer 15 is subjected to a first heating at a temperature of about 40° C. to about 140° C. for about 10 seconds to about 5 minutes, as shown in FIG. 10B. In some embodiments, the first heating is performed at a temperature of about 60° C. to about 130° C. for about 20 seconds to about 3 minutes. In other embodiments, the first heating is performed at a temperature of about 80° C. to about 120° C. for about 30 seconds to about 2 minutes.

A photoresist composition is subsequently disposed over the substrate 10 to form a photoresist layer 20, as shown in FIG. 10C. The photoresist layer 20 is formed of the same components and in a similar manner as disclosed herein with respect to FIG. 1C.

In some embodiments, the method includes a second heating of the photoresist under-layer 15a and the photoresist layer 20 at a temperature of about 40° C. to about 140° C. for about 10 seconds to about 5 minutes after the photoresist layer 20 is disposed over the photoresist under-layer 15a, as shown in FIG. 10D. The second heating removes solvent from the photoresist layer. In some embodiments, the photoresist layer 20 and the photoresist under-layer 15a are heated at a temperature of about 60° C. to about 120° C. for about 20 seconds to about 3 minutes.

Then, as shown in FIG. 10E, a portion of the photoresist layer 20b is selectively exposed to actinic radiation 30. In some embodiments, a mask 25 is used to form the exposed portions 20b and unexposed portions 20a of the photoresist layer, and exposed portions 15b and unexposed portions 15a of the photoresist under-layer. In some embodiments, the exposure to actinic radiation is performed in the manner as disclosed with reference to FIGS. 1E and 6E in some embodiments. The actinic radiation exposure causes the photobase generator to generate a base in the portions 15b of the photoresist under-layer exposed to actinic radiation.

The photoresist under-layer 15 and photoresist layer 20 are then subjected to a third heating or post-exposure baking (PEB) operation in some embodiments, as shown in FIG. 10F. The PEB is performed at a temperature of about 140° C. to about 200° C. for about 10 seconds to about 10 minutes. During the PEB operation, the thermal acid generator is heated to a temperature to trigger the generation of acid in the exposed portions 20b of the photoresist layer. The acid generated by the TAG in the photoresist under-layer 15 is neutralized by the base generated by the photobase generator in some embodiments. The generated acid furthers the chemical changes, such as the ALG de-protect reaction illustrated in FIG. 2C in the photoresist layer. In addition, the generated acid catalyzes a reaction between the alcohol and the carboxylic acid groups on the polymer, thereby converting carboxylic acid groups to ester groups and improving solubility of the polymer in the photoresist developer. In some embodiments, the PEB heating temperature is in a range of about 150° C. to about 180° C. for about 30 seconds to about 5 minutes.

Development is subsequently performed, as shown in FIG. 10G, using a solvent, to form a pattern 35 in the photoresist layer and photoresist under-layer. The development operation is performed in a similar manner as disclosed herein in reference to FIGS. 1G, 6G, and 8G in some embodiments. In some embodiments where negative tone development is desired, an organic solvent or critical fluid is used to remove the unexposed portions 20a of the photoresist. In some embodiments, the negative tone developer includes one or more selected from hexane, heptane, octane, toluene, xylene, dichloromethane, chloroform, carbon tetrachloride, trichloroethylene, and like hydrocarbon solvents; critical carbon dioxide, methanol, ethanol, propanol, butanol, and like alcohol solvents; diethyl ether, dipropyl ether, dibutyl ether, ethyl vinyl ether, dioxane, propylene oxide, tetrahydrofuran, cellosolve, methyl cellosolve, butyl cellosolve, methyl carbitol, diethylene glycol monoethyl ether and like ether solvents; acetone, methyl ethyl ketone, methyl isobutyl ketone, isophorone, cyclohexanone and like ketone solvents; methyl acetate, ethyl acetate, propyl acetate, butyl acetate and like ester solvents; pyridine, formamide, and N,N-dimethyl formamide or the like.

Additional processing is performed while the patterned photoresist layer is in place in some embodiments. For example, an etching operation, using dry or wet etching, is performed in some embodiments, to transfer the pattern 35 of the photoresist layer to the substrate 10, thereby forming pattern 35′ in the substrate, as shown in FIG. 10H. As explained with reference to FIGS. 1H, 6H, and 8H the remaining photoresist layer is subsequently removed by a suitable photoresist stripping or photoresist ashing operation, as shown in FIG. 10H. In some embodiments, the portion 15b of the photoresist under-layer exposed to actinic radiation remains on the substrate 10. In other embodiments, the exposed portions 15b of the photoresist under-layer are removed during the photoresist stripping, photoresist ashing, or substrate etching operation.

FIGS. 10I and 10J are cross sectional views of an alternative embodiment of manufacturing a semiconductor device according to the disclosure. FIG. 10I illustrates a semiconductor substrate 10 with a layer to be patterned 50 disposed thereon, and the photoresist under-layer 15 disposed over the layer to be patterned 50. In some embodiments, the layer to be patterned 50 is a hard mask layer; metallization layer; or a dielectric layer, such as a passivation layer, disposed over a metallization layer. In some embodiments, the structure illustrated in FIG. 10I is processed in the same manner as disclosed with reference to FIGS. 10A-10H to provide the structure of FIG. 8J.

FIGS. 10K and 10L are cross sectional views of an alternative embodiment of manufacturing a semiconductor device according to the disclosure. FIG. 10K illustrates a mid-layer 100 and bottom layer 95 of a tri-layer resist disposed over the substrate 10. A layer to be patterned 50, as discussed above, is disposed over the substrate 10 in some embodiments. In some embodiments, the structure illustrated in FIG. 10K is processed in the same manner as disclosed with reference to FIGS. 10A to 10J to provide the structure of FIG. 10L.

In addition to the polymer resins, the PACs, the solvents, the cross-linking agent, and the coupling reagent, some embodiments of the photoresist also includes a number of other additives that assist the photoresist to obtain high resolution. For example, some embodiments of the photoresist also include surfactants in order to help improve the ability of the photoresist to coat the surface on which it is applied. In some embodiments, the surfactants include nonionic surfactants, polymers having fluorinated aliphatic groups, surfactants that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, and polyoxyethylene sorbitan fatty acid esters.

Specific examples of materials used as surfactants in some embodiments include polyoxyethylene lauryl ether, polyoxyethylene stearyl ether, polyoxyethylene cetyl ether, polyoxyethylene oleyl ether, polyoxyethylene octyl phenol ether, polyoxyethylene nonyl phenol ether, sorbitan monolaurate, sorbitan monopalmitate, sorbitan monostearate, sorbitan monooleate, sorbitan trioleate, sorbitan tristearate, polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, polyethylene glycol distearate, polyethylene glycol dilaurate, polyethylene glycol dilaurate, polyethylene glycol, polypropylene glycol, polyoxyethylenestearyl ether, polyoxyethylene cetyl ether, fluorine containing cationic surfactants, fluorine containing nonionic surfactants, fluorine containing anionic surfactants, cationic surfactants and anionic surfactants, polyethylene glycol, polypropylene glycol, polyoxyethylene cetyl ether, combinations thereof, or the like.

Another additive added to some embodiments of the photoresist composition is a quencher, which inhibits diffusion of the generated acids/bases/free radicals within the photoresist. The quencher improves the resist pattern configuration as well as the stability of the photoresist over time. In an embodiment, the quencher is an amine, such as a second lower aliphatic amine, a tertiary lower aliphatic amine, or the like. Specific examples of amines include trimethylamine, diethylamine, triethylamine, di-n-propylamine, tri-n-propylamine, tripentylamine, diethanolamine, and triethanolamine, alkanolamine, combinations thereof, or the like.

Some embodiments of quenchers include:

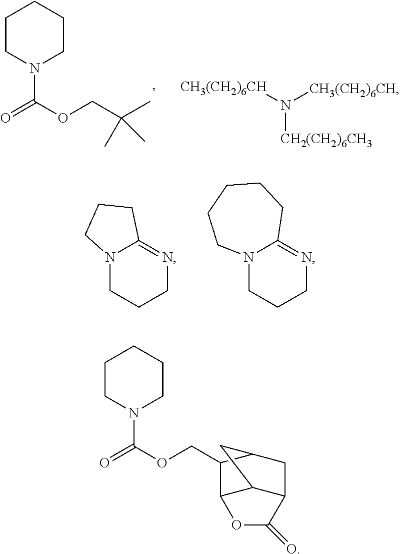

In some embodiments, an organic acid is used as the quencher. Specific embodiments of organic acids include malonic acid, citric acid, malic acid, succinic acid, benzoic acid, salicylic acid; phosphorous oxo acid and its derivatives, such as phosphoric acid and derivatives thereof such as its esters, phosphoric acid di-n-butyl ester and phosphoric acid diphenyl ester; phosphonic acid and derivatives thereof such as its ester, such as phosphonic acid dimethyl ester, phosphonic acid di-n-butyl ester, phenylphosphonic acid, phosphonic acid diphenyl ester, and phosphonic acid dibenzyl ester; and phosphinic acid and derivatives thereof such as its esters, including phenylphosphinic acid.

Another additive added to some embodiments of the photoresist is a stabilizer, which assists in preventing undesired diffusion of the acids generated during exposure of the photoresist. In some embodiments, the stabilizer includes nitrogenous compounds, including aliphatic primary, secondary, and tertiary amines; cyclic amines, including piperidines, pyrrolidines, morpholines; aromatic heterocycles, including pyridines, pyrimidines, purines; imines, including diazabicycloundecene, guanidines, imides, amides, or the like. Alternatively, ammonium salts are also used for the stabilizer in some embodiments, including primary, secondary, tertiary, and quaternary alkyl- and aryl-ammonium salts of alkoxides, including hydroxide, phenolates, carboxylates, aryl and alkyl sulfonates, sulfonamides, or the like. Other cationic nitrogenous compounds, including pyridinium salts and salts of other heterocyclic nitrogenous compounds with anions, such as alkoxides, including hydroxide, phenolates, carboxylates, aryl and alkyl sulfonates, sulfonamides, or the like, are used in some embodiments.

Another additive in some embodiments of the photoresist is a dissolution inhibitor to help control dissolution of the photoresist during development. In an embodiment bile-salt esters may be utilized as the dissolution inhibitor. Specific examples of dissolution inhibitors in some embodiments include cholic acid, deoxycholic acid, lithocholic acid, t-butyl deoxycholate, t-butyl lithocholate, and t-butyl-3-acetyl lithocholate.

A coloring agent is another additive included in some embodiments of the photoresist. The coloring agent aids observers in examining the photoresist to find any defects that may need to be remedied prior to further processing. In some embodiments, the coloring agent is a triarylmethane dye or a fine particle organic pigment. Specific examples of materials in some embodiments include crystal violet, methyl violet, ethyl violet, oil blue #603, Victoria Pure Blue BOH, malachite green, diamond green, phthalocyanine pigments, azo pigments, carbon black, titanium oxide, brilliant green dye (C. I. 42020), Victoria Pure Blue FGA (Linebrow), Victoria BO (Linebrow) (C. I. 42595), Victoria Blue BO (C. I. 44045), rhodamine 6G (C. I. 45160), benzophenone compounds, such as 2,4-dihydroxybenzophenone and 2,2′,4,4′-tetrahydroxybenzophenone; salicylic acid compounds, such as phenyl salicylate and 4-t-butylphenyl salicylate; phenylacrylate compounds, such as ethyl-2-cyano-3,3-diphenylacrylate, and 2′-ethylhexyl-2-cyano-3,3-diphenylacrylate; benzotriazole compounds, such as 2-(2-hydroxy-5-methylphenyl)-2H-benzotriazole, and 2-(3-t-butyl-2-hydroxy-5-methylphenyl)-5-chloro-2H-benzotriazole; coumarin compounds, such as 4-methyl-7-diethylamino-1-benzopyran-2-one; thioxanthone compounds, such as diethylthioxanthone; stilbene compounds, naphthalic acid compounds, azo dyes, phthalocyanine blue, phthalocyanine green, iodine green, Victoria blue, crystal violet, titanium oxide, naphthalene black, Photopia methyl violet, bromphenol blue and bromcresol green; laser dyes, such as Rhodamine G6, Coumarin 500, DCM (4-(dicyanomethylene)-2-methyl-6-(4-dimethylaminostyryl)-4H pyran)), Kiton Red 620, Pyrromethene 580, or the like. Additionally, one or more coloring agents may be used in combination to provide the desired coloring.

Surface leveling agents are added to some embodiments of the photoresist to assist a top surface of the photoresist to be level, so that impinging light will not be adversely modified by an unlevel surface. In some embodiments, surface leveling agents include fluoroaliphatic esters, hydroxyl terminated fluorinated polyethers, fluorinated ethylene glycol polymers, silicones, acrylic polymer leveling agents, combinations thereof, or the like.

Additional processing operations are performed in some embodiments to manufacture semiconductor devices. In some embodiments, the fabrication process includes an ion implantation process applied to the wafer using the patterned resist layer as an implantation mask, thereby forming various doped features in the wafer.

Other embodiments include other operations before, during, or after the operations described above. In an embodiment, the method includes forming fin field effect transistor (FinFET) structures. In some embodiments, a plurality of active fins are formed on the semiconductor substrate. Such embodiments, further include etching the substrate through the openings of the patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In another embodiment, the method includes other operations to form a plurality of gate electrodes on the semiconductor substrate. The method may further include forming gate spacers, doped source/drain regions, contacts for gate/source/drain features, etc. In another embodiment, a target pattern is to be formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, the semiconductor substrate 10 is an intermediate structure fabricated during processing of an IC, or a portion thereof, that may include logic circuits, memory structures, passive components (such as resistors, capacitors, and inductors), and active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, fin-like FETs (FinFETs), other three-dimensional (3D) FETs, metal-oxide semiconductor field effect transistors (MOSFET), complementary metal-oxide semiconductor (CMOS) transistors, bipolar transistors, high voltage transistors, high frequency transistors, other memory cells, and combinations thereof.

Embodiments of the present disclosure provide improved removal of residual photoresist and scum after development. Embodiments of the present disclosure provide improved line width resolution of photoresist patterns. Embodiments of the present disclosure provide a 30% or greater improvement in the after development inspection and after etching inspection defect rate.

An embodiment of the disclosure is a method of manufacturing a semiconductor device, including forming a photoresist under-layer including a photoresist under-layer composition over a semiconductor substrate, and forming a photoresist layer including a photoresist composition over the photoresist under-layer. The photoresist layer is selectively exposed to actinic radiation and the photoresist layer is developed to form a pattern in the photoresist layer. The photoresist under-layer composition includes a polymer having pendant acid-labile groups, a polymer having crosslinking groups or a polymer having pendant carboxylic acid groups, an acid generator, and a solvent. The photoresist composition includes a polymer, a photoactive compound, and a solvent. In an embodiment, the acid generator is a photoacid generator or a thermal acid generator. In an embodiment, the method includes a first heating of the photoresist under-layer at a temperature of 40° C. to 200° C. for 10 seconds to 5 minutes before forming the photoresist layer. In an embodiment, the photoresist composition comprises a metal-containing photoresist. In an embodiment, the method includes a second heating of the photoresist layer and the photoresist under-layer at a temperature of 40° C. to 140° C. for 10 seconds to 5 minutes. In an embodiment, the method includes a third heating of the photoresist under-layer and the selectively exposed photoresist layer at a temperature of 100° C. to 200° C. for about 10 seconds to about 10 minutes before developing the selectively exposed photoresist layer. In an embodiment, the pendant acid-labile groups are 20 wt. % to 80 wt. % of the polymer having pendant acid-labile groups. In an embodiment, the crosslinking groups are 20 wt. % to 80 wt. % of the polymer having the crosslinking groups. In an embodiment, the pendant carboxylic acid groups are 5 wt. % to 30 wt. % of the polymer having the pendant carboxylic acid groups. In an embodiment, the portion of the photoresist selectively exposed to actinic radiation is removed during the developing. In an embodiment, the acid labile group is connected to the polymer having the pendant acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is selected from the group consisting of

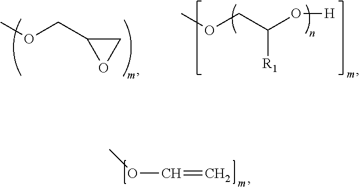

where m ranges from 1 to 6 and m/n ranges from 1 to 6. In an embodiment, the under-layer composition comprises 5 wt. % to 40 wt. % of the acid generator based on the weight of the acid generator and the polymer having pendant acid labile groups. In an embodiment, the photoacid generator is selected from the group consisting of

| cation | anion |
|---|---|
| 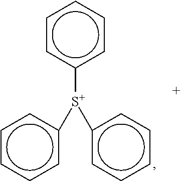 | 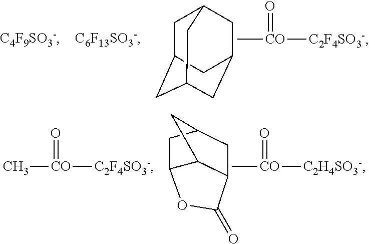 |
| 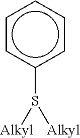 | 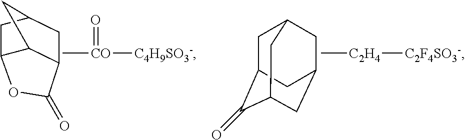 |
| | 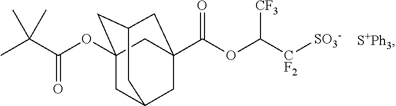 |
| | 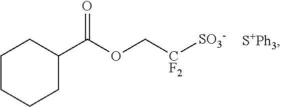 |
| | 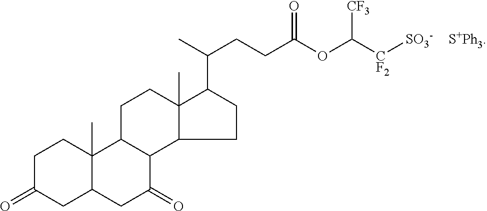 |

In an embodiment, the acid-labile group is selected from the group consisting of

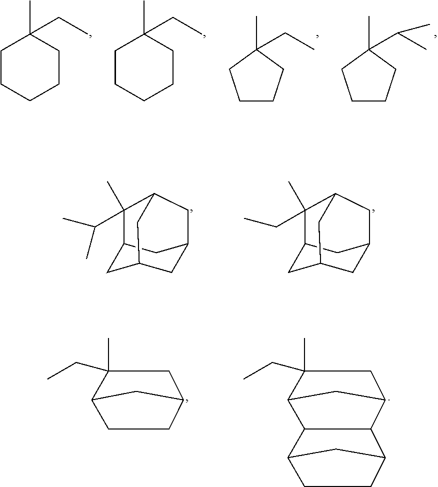

In an embodiment, the thermal acid generator is selected from the group consisting of

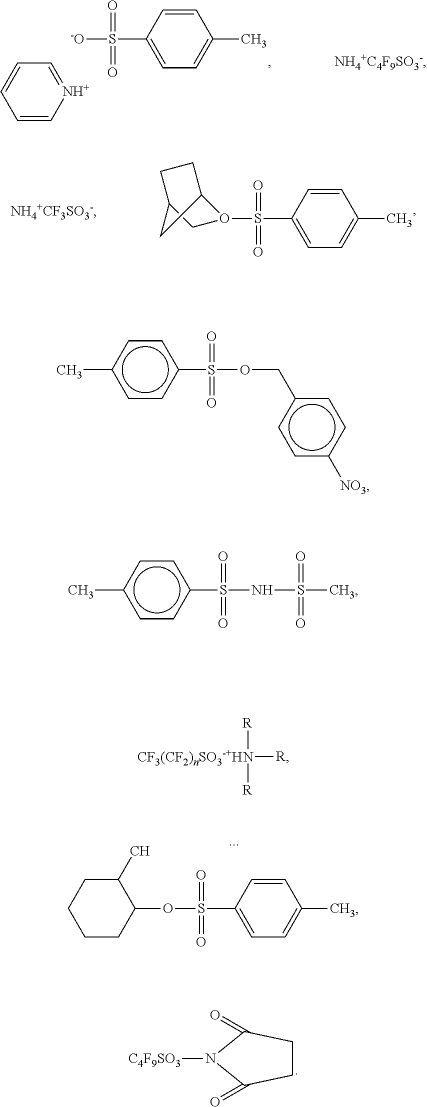

In an embodiment, the photoresist under-layer is a bottom layer or a middle layer of a tri-layer resist. In an embodiment, the photoresist under-layer is disposed over a bottom layer or a middle layer of a tri-layer resist.

Another embodiment of the disclosure is a method of manufacturing a semiconductor device, including forming a photoresist under-layer including a photoresist under-layer composition over a semiconductor substrate, and forming a photoresist layer including a photoresist composition over the photoresist under-layer. The photoresist layer is selectively exposed to actinic radiation, and the photoresist layer is developed to form a pattern in the photoresist layer. The photoresist under-layer composition includes a polymer having pendant acid-labile groups or a polymer having pendant carboxylic acid groups, an alcohol or a polymer having crosslinking groups, a thermal acid generator, a photobase generator, and a solvent. The photoresist composition includes a polymer, a photoactive compound, and a solvent. In an embodiment, the method includes a first heating of the photoresist under-layer at a temperature of 40° C. to 140° C. for 10 seconds to 5 minutes before forming the photoresist layer. In an embodiment, the photoresist composition comprises a metal-containing photoresist. In an embodiment, the method includes a second heating of the photoresist layer and the photoresist under-layer at a temperature of 40° C. to 140° C. for 10 seconds to 5 minutes. In an embodiment, the method includes a third heating of the photoresist under-layer and the selectively exposed photoresist layer at a temperature about 140° C. and 200° C. for about 10 seconds to about 10 minutes before developing the selectively exposed photoresist layer. In an embodiment, the pendant acid-labile groups or pendant carboxylic acid groups are 10 wt. % to 60 wt. % of the polymer having pendant acid-labile or pendant carboxylic acid groups. In an embodiment, the crosslinking groups are 10 wt. % to 60 wt. % of the polymer having the crosslinking groups. In an embodiment, the portion of the photoresist not selectively exposed to actinic radiation is removed during the developing. In an embodiment, the acid labile group is connected to the polymer having the pendant acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is selected from the group consisting of

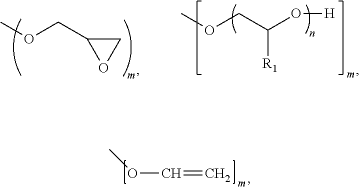

where m ranges from 1 to 6 and m/n ranges from 1 to 6. In an embodiment, the under-layer composition comprises 5 wt. % to 40 wt. % of the acid generator based on the weight of the acid generator and the polymer having pendant acid-labile groups. In an embodiment, the under-layer composition comprises 5 wt. % to 40 wt. % of the photobase generator based on the weight of the photobase generator and the polymer having pendant acid-labile groups or having carboxylic acid groups. In an embodiment, the acid labile group is selected from the group consisting of

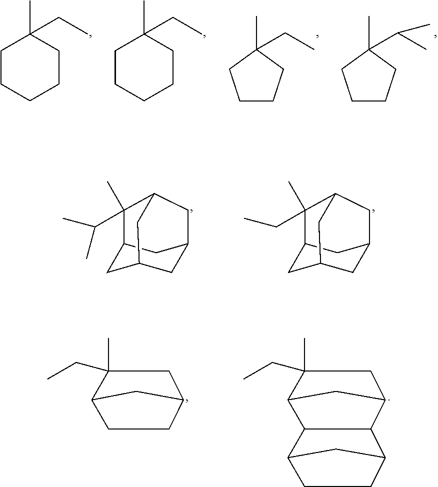

In an embodiment, the photobase generator is selected from the group consisting of

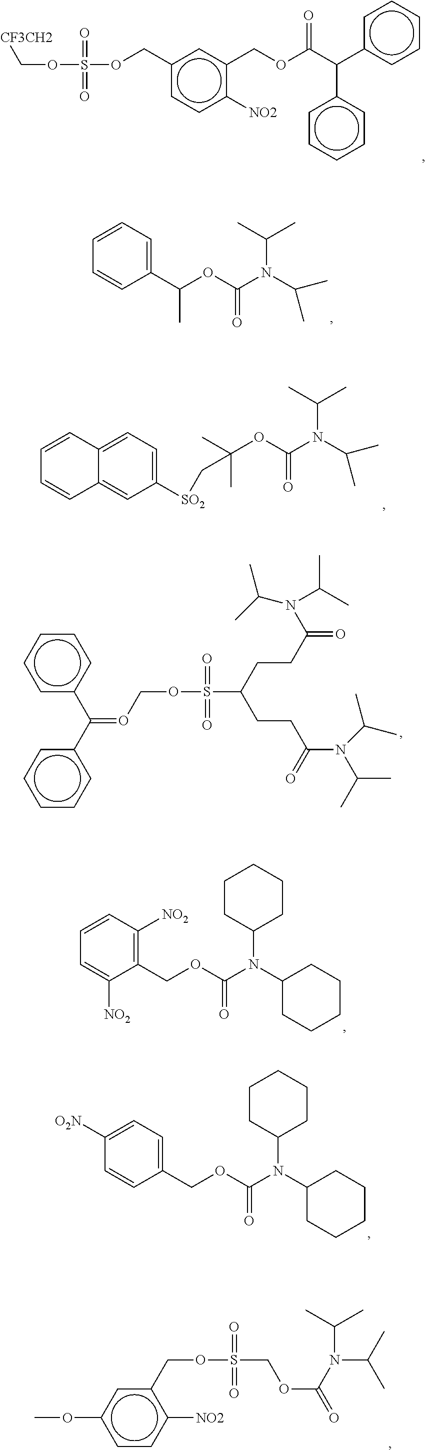

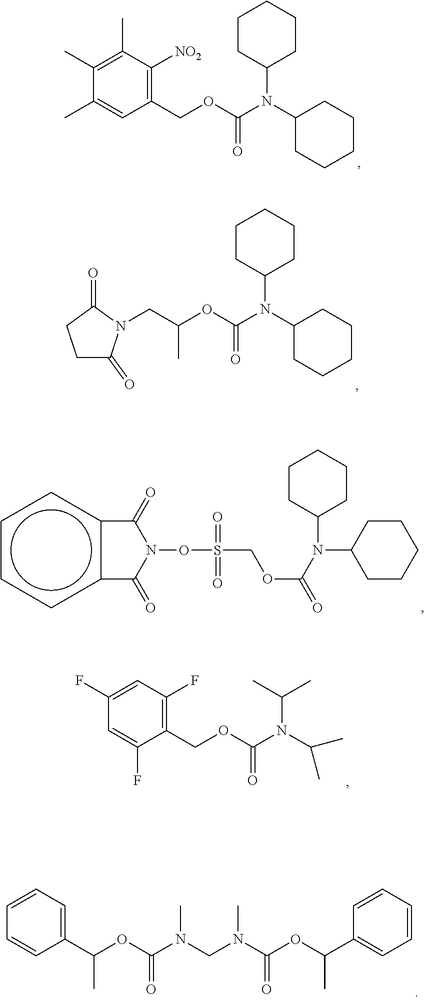

In an embodiment, the under-layer composition comprises 5 wt. % to 40 wt. % of alcohol based on the weight of the alcohol and the polymer having pendant carboxylic acid groups. In an embodiment, the alcohol is selected from the group consisting of
CH₃OH, C₂H₄(OH)₂, C₃H₅(OH)₃, C₄H₆(OH)₄, C₃H₇OH, C₅H₁₀(OH)₂, C₅H₉(OH)₃, C₆H₁₀(OH)₄, C₅H₁₁OH, C₇H₁₄(OH)₂, C₈H₁₅(OH)₃, C₉H₁₆(OH)₄.

Another embodiment of the disclosure is a composition, including: a polymer having pendant acid-labile groups, wherein the acid-labile groups are 20 wt. % to 80 wt. % of the polymer having pendant acid-labile groups, and a polymer having crosslinking groups or a polymer having pendant carboxylic acid groups. The crosslinking groups are 20 wt. % to 80 wt. % of the polymer having the crosslinking groups, and the carboxylic acid groups are 5 wt. % to 30 wt. % of the polymer having the carboxylic acid groups. The composition includes an acid generator, and a solvent. In an embodiment, the acid generator is a photoacid generator or a thermal acid generator. In an embodiment, the acid-labile group is connected to the polymer having the pendant acid-labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is selected from the group consisting of

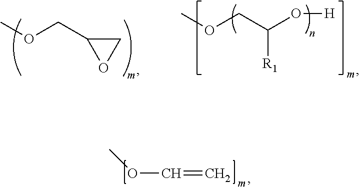

where m ranges from 1 to 6 and m/n ranges from 1 to 6. In an embodiment, the under-layer composition comprises 5 wt. % to 40 wt. % of the acid generator based on the weight of the acid generator and the polymer having pendant acid labile groups. In an embodiment, the photoacid generator is selected from the group consisting of

| cation | anion |
|---|---|
| 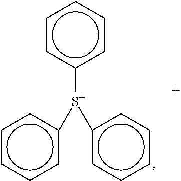 | 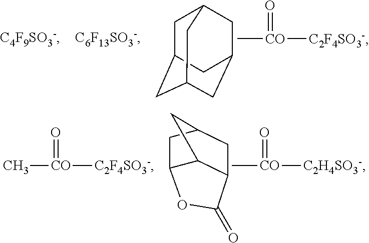 |
| 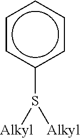 | 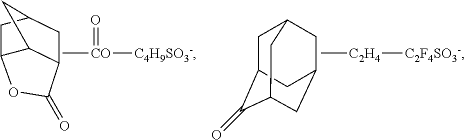 |
| | 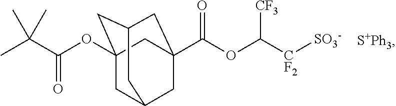 |
| | 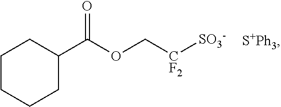 |
| | 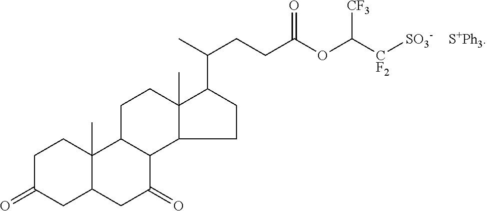 |

In an embodiment, the acid labile group is selected from the group consisting of

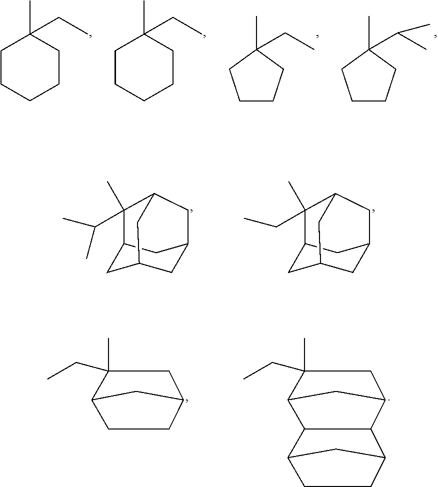

In an embodiment, the thermal acid generator is selected from the group consisting of

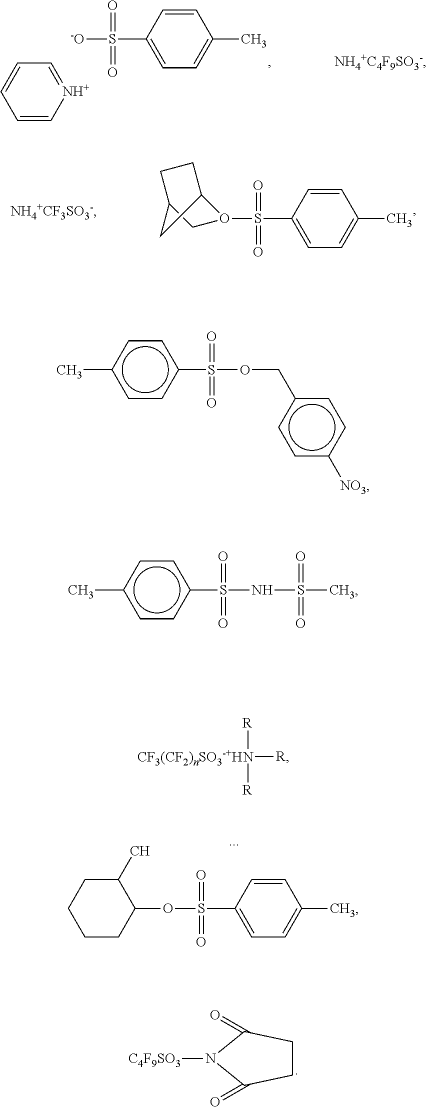

Another embodiment of the disclosure is a method of manufacturing a semiconductor device, including forming a photoresist layer including a photoresist composition over a semiconductor substrate, and forming a photoresist over-layer including a photoresist over-layer composition over the photoresist under-layer. The photoresist over-layer and photoresist layer are selectively exposed to actinic radiation, and the photoresist layer over-layer and photoresist layer are developed to form a pattern in the photoresist layer. In an embodiment, the photoresist over-layer is made of a composition including a polymer having pendant carboxylic acid groups, a thermal acid generator, a photobase generator, an alcohol, and a solvent. The photoresist layer is made of a composition including a polymer, a photoactive compound, and a solvent. In an embodiment, the method includes a first heating of the photoresist layer at a temperature of 40° C. to 140° C. for 10 seconds to 5 minutes before forming the photoresist over-layer. In an embodiment, the photoresist composition includes a metal-containing photoresist. In an embodiment, the method includes a second heating of the photoresist over-layer and the photoresist layer at a temperature of 40° C. to 140° C. for 10 seconds to 5 minutes. In an embodiment, the method includes a third heating of the selectively exposed photoresist over-layer and the selectively exposed photoresist layer at a temperature of 140° C. to 200° C. for 10 seconds to 10 minutes before developing the selectively exposed photoresist layer. In an embodiment, the pendant carboxylic acid groups are 10 wt. % to 60 wt. % of the polymer having pendant carboxylic acid groups. In an embodiment, the portion of the photoresist layer and photoresist over-layer not selectively exposed to actinic radiation is removed during the developing.

Another embodiment of the disclosure is a composition, including a polymer having pendant acid-labile groups. The acid-labile groups are 10 wt. % to 60 wt. % of the polymer having pendant acid-labile groups. The composition includes a polymer having crosslinking groups, wherein the crosslinking groups are 10 wt. % to 60 wt. % of the polymer having the crosslinking groups, and the carboxylic acid groups are 5 wt. % to 30 wt. % of the polymer having the carboxylic acid groups. The composition also includes a thermal acid generator, a photobase generator, and a solvent. In an embodiment, the acid labile group is connected to the polymer having the pendant acid labile groups by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is connected to the polymer with a crosslinking group by a connecting group selected from substituted and unsubstituted, branched and unbranched aliphatic groups, branched and unbranched aromatic groups, 1-9 carbon cyclic and non-cyclic groups, unsubstituted or halogen-substituted, or —S—, —P—, —P(O₂)—, —C(═O)S—, —C(═O)O—, —O—, —N—, —C(═O)N—, —SO₂O—, —SO₂S—, —SO—, and —SO₂—, or a carboxylic acid group, ether group, ketone group, ester group, or benzene group. In an embodiment, the crosslinking group is selected from the group consisting of

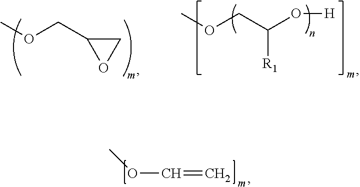

where m ranges from 1 to 6 and m/n ranges from 1 to 6. In an embodiment, the composition comprises 5 wt. % to 40 wt. % of the thermal acid generator based on the weight of the thermal acid generator and the polymer having pendant acid labile groups. In an embodiment, the composition comprises 5 wt. % to 40 wt. % of the photobase generator based on the weight of the photobase generator and the polymer having pendant acid labile groups. In an embodiment, the acid labile group is selected from the group consisting of

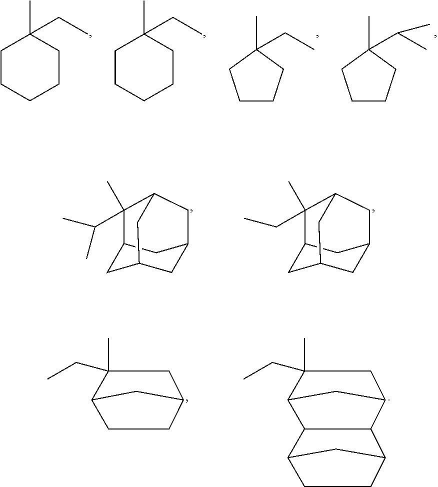

In an embodiment, the photobase generator is selected from the group consisting of

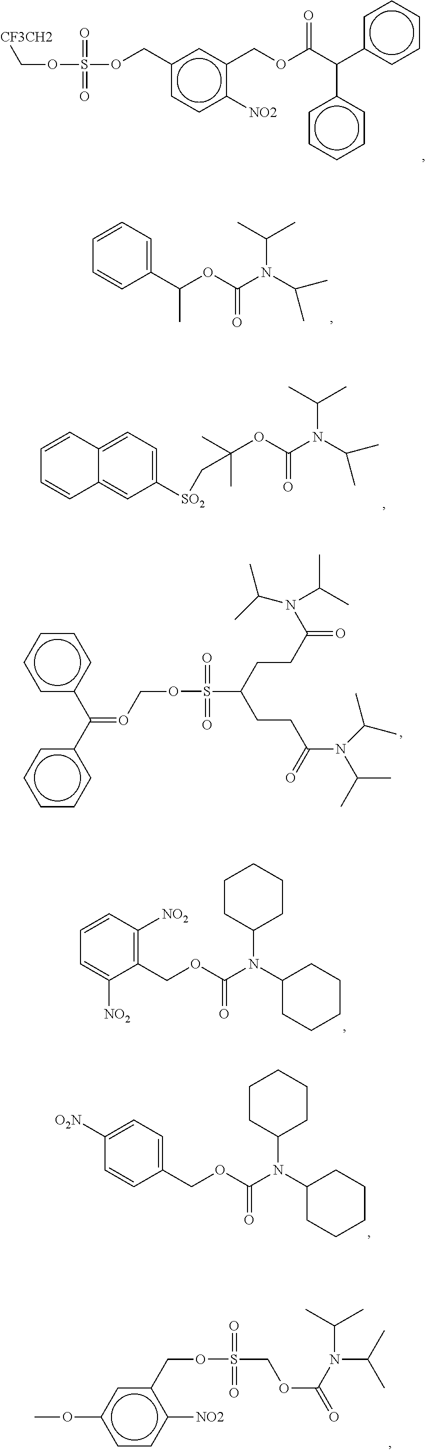

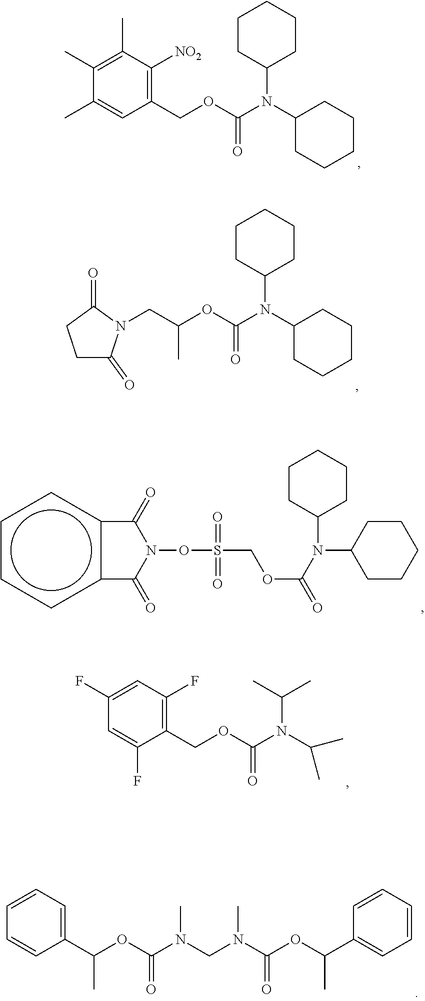

In an embodiment, the thermal acid generator is selected from the group consisting of

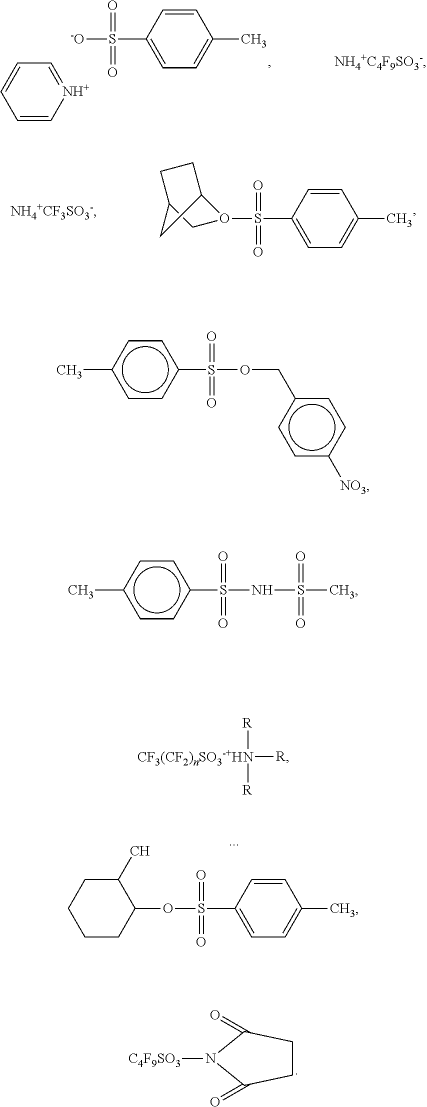

Another embodiment of the disclosure is a composition, including a polymer having pendant carboxylic acid groups, wherein the pendant carboxylic acid groups are 10 wt. % to 60 wt. % of the polymer having pendant carboxylic acid groups. The composition includes a thermal acid generator, a photobase generator, an alcohol, and a solvent. In an embodiment, the composition comprises 5 wt. % to 40 wt. % of the thermal acid generator based on the weight of the thermal acid generator and the polymer having pendant carboxylic acid groups. In an embodiment, the composition comprises 5 wt. % to 40 wt. % of the photobase generator based on the weight of the photobase generator and the polymer having carboxylic acid groups. In an embodiment, the acid labile group is selected from the group consisting of

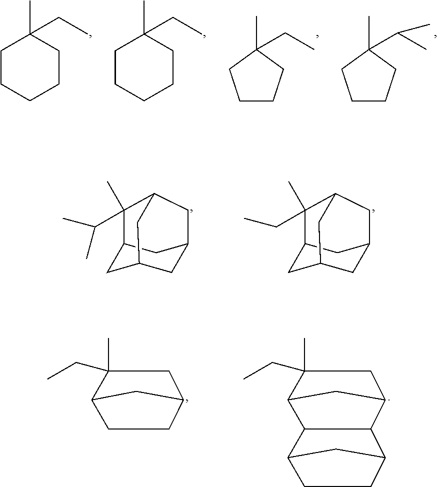

In an embodiment, the photobase generator is selected from the group consisting of

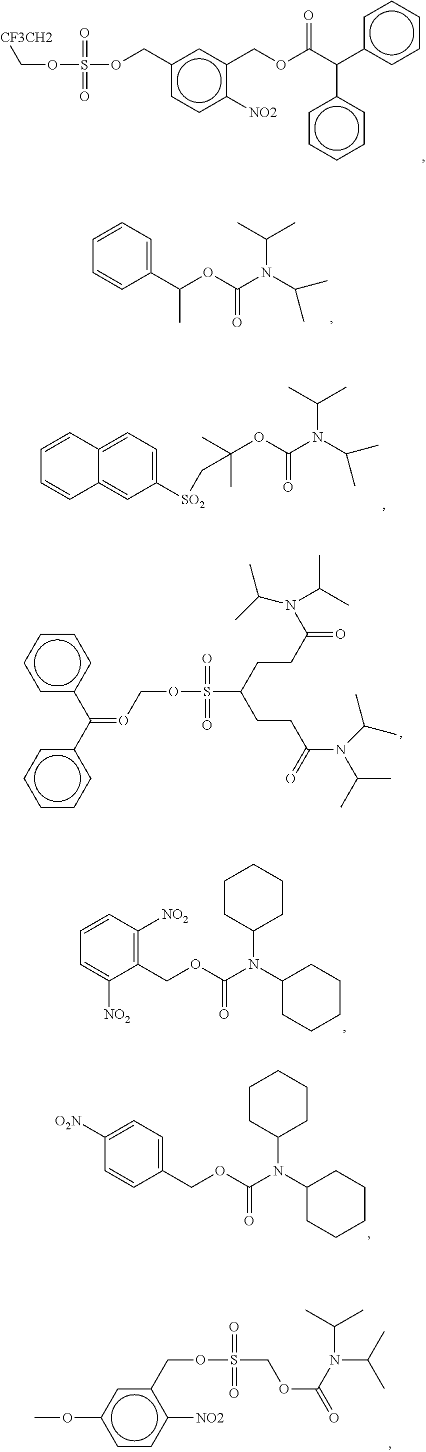

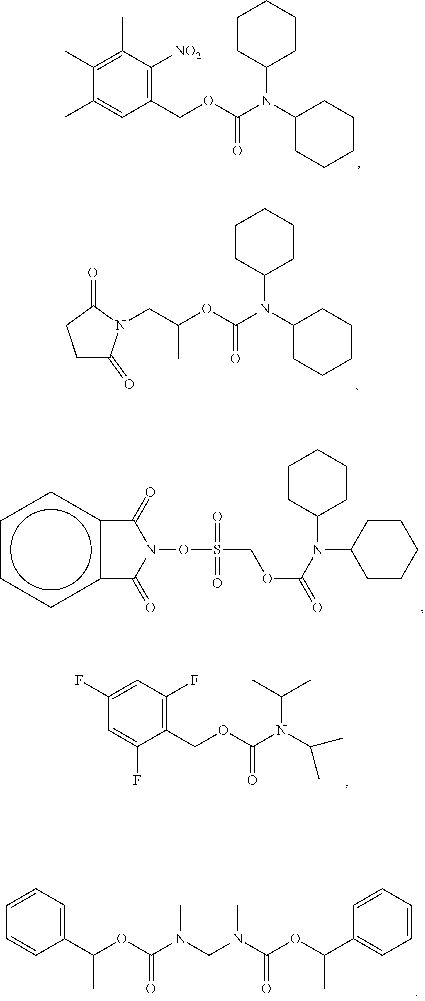

In an embodiment, the thermal acid generator is selected from the group consisting of

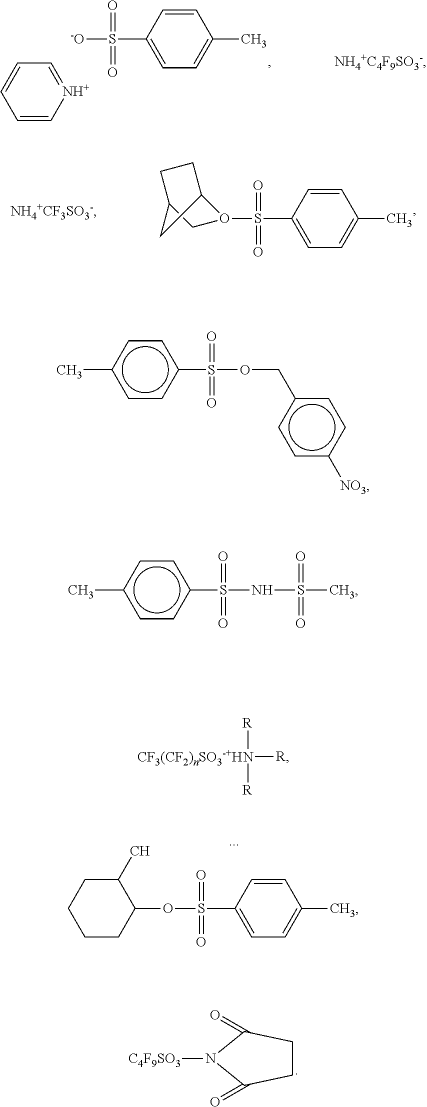

In an embodiment, the composition comprises 5 wt. % to 40 wt. % of alcohol based on the weight of the alcohol and the polymer having pendant carboxylic acid groups. In an embodiment, the alcohol is selected from the group consisting of
CH₃OH, C₂H₄(OH)₂, C₃H₅(OH)₃, C₄H₆(OH)₄, C₃H₇OH, C₅H₁₀(OH)₂, C₅H₉(OH)₃, C₆H₁₀(OH)₄, C₅H₁₁OH, C₇H₁₄(OH)₂, C₈H₁₅(OH)₃, C₉H₁₆(OH)₄.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a photoresist under-layer comprising a photoresist under-layer composition over a semiconductor substrate;
forming a photoresist layer comprising a photoresist composition over the photoresist under-layer;
selectively exposing the photoresist layer to actinic radiation; and
developing the photoresist layer to form a pattern in the photoresist layer,
wherein the photoresist under-layer composition comprises:
a polymer having pendant acid-labile groups;
a polymer having crosslinking groups or a polymer having pendant carboxylic acid groups;
an acid generator; and
a solvent, and
wherein the photoresist composition comprises:
a polymer;
a photoactive compound; and
a solvent.

2. The method according to claim 1, wherein the acid generator is a photoacid generator or a thermal acid generator.

3. The method according to claim 1, further comprising a first heating of the photoresist under-layer at a temperature of 40° C. to 200° C. for 10 seconds to 5 minutes before forming the photoresist layer.

4. The method according to claim 1, wherein the photoresist composition comprises a metal-containing photoresist.

5. The method according to claim 1, further comprising a second heating of the photoresist layer and the photoresist under-layer at a temperature of 40° C. to 140° C. for 10 seconds to 5 minutes.

6. The method according to claim 1, further comprising a third heating of the photoresist under-layer and the selectively exposed photoresist layer at a temperature of 100° C. to 200° C. for 10 seconds to 10 minutes before developing the selectively exposed photoresist layer.

7. The method according to claim 1, wherein the pendant acid-labile groups are 20 wt. % to 80 wt. % of the polymer having pendant acid-labile groups.

8. The method according to claim 1, wherein the crosslinking groups are 20 wt. % to 80 wt. % of the polymer having the crosslinking groups.

9. The method according to claim 1, wherein the pendant carboxylic acid groups are 5 wt. % to 30 wt. % of the polymer having the pendant carboxylic acid groups.

10. The method according to claim 1, wherein the portion of the photoresist selectively exposed to actinic radiation is removed during the developing.

11. A method of manufacturing a semiconductor device, comprising:
forming a photoresist under-layer comprising a photoresist under-layer composition over a semiconductor substrate;
forming a photoresist layer comprising a photoresist composition over the photoresist under-layer;
selectively exposing the photoresist layer to actinic radiation; and
developing the photoresist layer to form a pattern in the photoresist layer,
wherein the photoresist under-layer composition comprises:
a polymer having pendant acid-labile groups or a polymer having pendant carboxylic acid groups;
an alcohol or a polymer having crosslinking groups;
a thermal acid generator;
a photobase generator; and
a solvent, and
wherein the photoresist composition comprises:
a polymer;
a photoactive compound; and
a solvent.

12. The method according to claim 11, further comprising a first heating of the photoresist under-layer at a temperature of 40° C. to 140° C. for 10 seconds to 5 minutes before forming the photoresist layer.

13. The method according to claim 11, wherein the photoresist composition comprises a metal-containing photoresist.

14. The method according to claim 11, further comprising a second heating of the photoresist layer and the photoresist under-layer at a temperature of 40° C. to 140° C. for 10 seconds to 5 minutes.

15. The method according to claim 11, further comprising a third heating of the photoresist under-layer and the selectively exposed photoresist layer at a temperature of 140° C. to 200° C. for 10 seconds to 10 minutes before developing the selectively exposed photoresist layer.

16. The method according to claim 11, wherein the pendant acid-labile groups or pendant carboxylic acid groups are 10 wt. % to 60 wt. % of the polymer having pendant acid-labile or pendant carboxylic acid groups.

17. The method according to claim 11, wherein the crosslinking groups are 10 wt. % to 60 wt. % of the polymer having the crosslinking groups.

18. The method according to claim 11, wherein the portion of the photoresist not selectively exposed to actinic radiation is removed during the developing.

19. A composition, comprising:
a polymer having pendant acid-labile groups, wherein the acid-labile groups are 20 wt. % to 80 wt. % of the polymer having pendant acid-labile groups;
a polymer having crosslinking groups or a polymer having pendant carboxylic acid groups,
wherein the crosslinking groups are 20 wt. % to 80 wt. % of the polymer having the crosslinking groups, and the carboxylic acid groups are 5 wt. % to 30 wt. % of the polymer having the carboxylic acid groups;
an acid generator; and
a solvent.

20. The composition of claim 19, wherein the acid generator is a photoacid generator or a thermal acid generator.
